(19) United States
(12) Patent Application Publication
(10) Pub. No.: US 2025/0048688 A1
(43) Pub. Date: Feb. 6, 2025

(54) STACKED FIELD EFFECT TRANSISTORS

(71) Applicant: International Business Machines Corporation, Armonk, NY (US)

(72) Inventors: Ruilong Xie, Niskayuna, NY (US); Junli Wang, Slingerlands, NY (US); Shay Reboh, Guilderland, NY (US); John Christopher Arnold, North Chatham, NY (US); Indira Seshadri, Niskayuna, NY (US); Chen Zhang, Santa Clara, CA (US); Tenko Yamashita, Schenectady, NY (US)

(21) Appl. No.: 18/228,261

(22) Filed: Jul. 31, 2023

(51) Int. Cl. H01L 29/06; H01L 21/8238; H01L 27/092; H01L 29/08; H01L 29/423; H01L 29/66; H01L 29/775; H01L 29/786

(52) U.S. Cl. CPC H01L 29/0673; H01L 21/823842; H01L 21/823871; H01L 27/092; H01L 29/0847; H01L 29/42392; H01L 29/66439; H01L 29/66545; H01L 29/775; H01L 29/78696

(57) ABSTRACT

A semiconductor device including stacked field effect transistors (FETs) is provided. The stacked FETs are formed utilizing a process that optimizes the thermal budget without negatively impacting the frontside and/or backside contact structures. The stacked can be designed to have different work function metals and a frontside/backside deep via structure can be provided that has a low area resistance.

### BACKGROUND

The present application relates to semiconductor technology, and more particularly to a semiconductor device including stacked field effect transistors (FETs).

Stacking of devices such as, for example, FETs, is an attractive architecture for future complementary metal oxide semiconductor (CMOS) scaling, and potentially for ultimately scaled technology. By directly stacking devices one over the other (for example, pFETs over nFETs, nFETs over pFETs, pFETs over pFETs, or nFETs over nFETs) significant area scaling can be achieved.

### SUMMARY

A semiconductor device including stacked FETs is provided. The stacked FETs are formed utilizing a process that optimizes the thermal budget without negatively impacting the frontside and/or backside contact structures. The stacked FETs of the present application can be designed to have different work function metals and a frontside/backside deep via structure can be provided that has a low area resistance.

In one aspect of the present application, a semiconductor device is provided. In one embodiment, the semiconductor device includes a first FET having a first gate structure and a pair of first source/drain regions and a second FET stacked over the first FET and having a second gate structure and a pair of second source/drain regions. The semiconductor device further includes a dielectric pillar located beneath the first FET and directly contacting one of the first source/drain regions of the pair of first source/drain regions, and a backside gate dielectric cap located adjacent to the dielectric pillar. In the present application, the backside gate dielectric cap directly contacts a surface of a first gate electrode of the first gate structure.

In another aspect of the present application, a process of forming a semiconductor device is provided. In one aspect of the present application, the process includes forming at least one precursor first gate structure including a first gate dielectric layer located on a surface of at least one first semiconductor channel material, and a first gate placeholder structure located on the first gate dielectric layer, wherein the at least one precursor first gate structure includes a pair of first source/drain regions, and wherein a dielectric pillar is located beneath one of the first source/drain regions of the pair of first source/drain regions, and a sacrificial placeholder structure is located beneath the other first source/drain region of the pair of first source/drain regions. Next, at least one second gate structure is formed above the at least one precursor first gate structure, the at least one second gate structure including a second gate dielectric layer located on a surface of at least one second semiconductor channel material, a second gate electrode located on the second gate dielectric layer, and a pair of second source/drain regions. At least frontside contact structures and a frontside BEOL structure are then formed on top of the second gate structure. Next, the first gate placeholder structure is replaced from a backside of the device with a first gate electrode, wherein the replacing converts the at least one precursor first gate structure into at least one first gate structure, and thereafter the sacrificial placeholder structure is replaced with a backside source/drain contact structure. Next, at least VSS power supplies and VDD power supplies and a backside BEOL structure are formed.

### BRIEF DESCRIPTION OF THE DRAWINGS

FIG. 1 is a top-down view of an exemplary semiconductor device layout that can be employed in accordance with an embodiment of the present application, the semiconductor device layout includes a plurality of active areas oriented along a first direction, and a plurality of functional gate structures that are oriented in a second direction which is perpendicular to the first direction; in the drawing cut A-A, cut B-B and cut C-C are shown.

FIGS. 2A, 2B and 2C are cross sectional views of an exemplary semiconductor structure corresponding to cuts A-A, B-B and C-C shown in FIG. 1, respectively, that can be employed in the present application, the semiconductor structure including a semiconductor substrate, an etch stop layer, and at least one first patterned material stack including alternating first sacrificial semiconductor material layers and first semiconductor channel material layers.

FIGS. 3A, 3B and 3C are cross sectional views of the exemplary semiconductor structure shown in FIGS. 2A, 2B and 2C, respectively, after forming at least one first sacrificial gate structure and at least one first gate spacer, nanosheet patterning of the at least one first patterned material stack to form at least one first nanosheet stack including alternating first sacrificial semiconductor material nanosheets and first semiconductor channel material nanosheets, recessing each first sacrificial semiconductor material nanosheet, and forming a first inner spacer adjacent to each recessed first sacrificial semiconductor material nanosheet.

FIGS. 4A, 4B and 4C are cross sectional views of the exemplary semiconductor structure shown in FIGS. 3A, 3B and 3C, respectively, after forming a sacrificial placeholder recess within the semiconductor substrate utilizing each first sacrificial gate structure and first gate spacer as a combined etch mask.

FIGS. 5A, 5B and 5C are cross sectional views of the exemplary semiconductor structure shown in FIGS. 4A, 4B and 4C, respectively, after forming a dielectric pillar in each sacrificial placeholder recess.

FIGS. 6A, 6B and 6C are cross sectional views of the exemplary semiconductor structure shown in FIGS. 5A, 5B and 5C, respectively, after removing at least one of the dielectric pillars.

FIGS. 7A, 7B and 7C are cross sectional views of the exemplary semiconductor structure shown in FIGS. 6A, 6B and 6C, respectively, after forming a sacrificial placeholder structure in the area previously occupied by the removed at least one dielectric pillar.

FIGS. 8A, 8B and 8C are cross sectional views of the exemplary semiconductor structure shown in FIGS. 7A, 7B and 7C, respectively, after forming first source/drain regions and a first frontside interlayer dielectric (ILD) layer.

FIGS. 9A, 9B and 9C are cross sectional views of the exemplary semiconductor structure shown in FIGS. 8A, 8B and 8C, respectively, after removing the at least one first sacrificial gate structure, and each first sacrificial semiconductor nanosheet to suspend a portion of each first semiconductor channel material nanosheet.

FIGS. 10A, 10B and 10C are cross sectional views of the exemplary semiconductor structure shown in FIGS. 9A, 9B and 9C, respectively, after forming a first gate dielectric layer wrapped around the suspended portion of each first semiconductor channel material nanosheet.

FIGS. 11A, 11B and 11C are cross sectional views of the exemplary semiconductor structure shown in FIGS. 10A, 10B and 10C, respectively, after forming a first gate placeholder structure on the first gate dielectric layer and forming first gate cut structures, each first gate cut structure including a first inner core dielectric material, and a first outer dielectric material liner.

FIGS. 12A, 12B and 12C are cross sectional views of the exemplary semiconductor structure shown in FIGS. 11A, 11B and 11C, respectively, after removing the first inner core dielectric material of some of the first gate cut structures and forming a first deep via structure in each area that was previously occupied by a removed first inner core dielectric material.

FIGS. 13A, 13B and 13C are cross sectional views of the exemplary semiconductor structure shown in FIGS. 12A, 12B and 12C, respectively, after forming a bonding dielectric layer and a second material stack of alternating second sacrificial semiconductor material layers and second semiconductor channel material layers.

FIGS. 14A, 14B and 14C are cross sectional views of the exemplary semiconductor structure shown in FIGS. 13A, 13B and 13C, respectively, after second device formation which includes patterning of the second material stack to form at least one second patterned material stack, forming at least one second sacrificial gate structure, forming second gate spacers, patterning the at least one second patterned material stack to form at least one second nanosheet stack, forming second inner spacers, forming second source/drain regions, forming a second frontside ILD layer, removing the at least one second sacrificial gate structure and each second sacrificial semiconductor material nanosheet of the at least one second nanosheet stack, forming a second gate dielectric layer and a second gate electrode wrapped around suspended portions of each second semiconductor channel material nanosheet of the at least one second nanosheet stack, and forming second gate cut structures, each second gate cut structure including a second inner core dielectric material, and a second outer dielectric material liner.

FIGS. 15A, 15B and 15C are cross sectional views of the exemplary semiconductor structure shown in FIGS. 14A, 14B and 14C, respectively, after removing the second inner core dielectric material of some of the second gate cut structures, revealing an underlying first deep via structure, and forming a second deep via structure contacting the revealed first deep via structure.

FIGS. 16A, 16B and 16C are cross sectional views of the exemplary semiconductor structure shown in FIGS. 15A, 15B and 15C, respectively, after forming additional frontside ILD layers having frontside contact structures, metal vias and metal lines embedded therein, a frontside back-end-of-the-line (BEOL) structure, and a carrier wafer.

FIGS. 17A, 17B and 17C are cross sectional views of the exemplary semiconductor structure shown in FIGS. 16A, 16B and 16C, respectively, after removing the semiconductor substrate.

FIGS. 18A, 18B and 18C are cross sectional views of the exemplary semiconductor structure shown in FIGS. 17A, 17B and 17C, respectively, after removing the etch stop layer to physically expose a portion of the first gate dielectric layer.

FIGS. 19A, 19B and 19C are cross sectional views of the exemplary semiconductor structure shown in FIGS. 18A, 18B and 18C, respectively, after removing the physically exposed portion of the first gate dielectric layer, and thereafter removing each first gate placeholder structure.

FIGS. 20A, 20B and 20C are cross sectional views of the exemplary semiconductor structure shown in FIGS. 19A, 19B and 19C, respectively, after forming a first gate electrode and forming a backside gate dielectric cap.

FIGS. 21A, 21B and 21C are cross sectional views of the exemplary semiconductor structure shown in FIGS. 20A, 20B and 20C, respectively, after removing each sacrificial placeholder structure to provide a backside contact opening that physically exposes some of the first source/drain regions.

FIGS. 22A, 22B and 22C are cross sectional views of the exemplary semiconductor structure shown in FIGS. 21A, 21B and 21C, respectively, after laterally recessing a physically exposed sidewall of the first gate electrode and forming an asymmetric inner spacer in the indented region of the first gate electrode.

FIGS. 23A, 23B and 23C are cross sectional views of the exemplary semiconductor structure shown in FIGS. 22A, 22B and 22C, respectively, after forming backside contact structures.

FIGS. 24A, 24B and 24C are cross sectional views of the exemplary semiconductor structure shown in FIGS. 23A, 23B and 23C, respectively, after forming a backside ILD layer containing backside VDD and VSS power structures embedded therein, and a backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In the present application, a semiconductor device is described and illustrated as containing stacked nanosheet transistors. A transistor (or FET) includes a source region, a drain region, a semiconductor channel region located between the source region and the drain region, and a gate structure located above the semiconductor channel region. Collectively, the source region and the drain region can be referred to as a source/drain region. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Stacked nanosheets transistors include a second nanosheet transistor stacked above a first nanosheet transistor. Although nanosheet transistors are described and illustrated, the present application can provide planar transistors, or other non-planar transistors such as, for example, semiconductor nanowire transistors and/or finFET transistors; each transistor being arranged in a stacked fashion, i.e., first and second transistors stacked one on top the other. In the present application, the semiconductor channel region can include at least one semiconductor channel material (the channel material can be planar, fin shaped, nanowire shaped or nanosheet shaped).

In the present application, the semiconductor device includes a frontside and a backside. The frontside of the semiconductor device of the present application includes a side of the device that includes the stacked transistors, frontside contact structures, and a frontside BEOL structure. The backside of the semiconductor device of the present application is the side of the device that is opposite the frontside (i.e., opposite the bottommost transistor of the stacked transistor configuration). The backside includes backside contact structure, VSS and VDD power supplies and a backside BEOL structure.

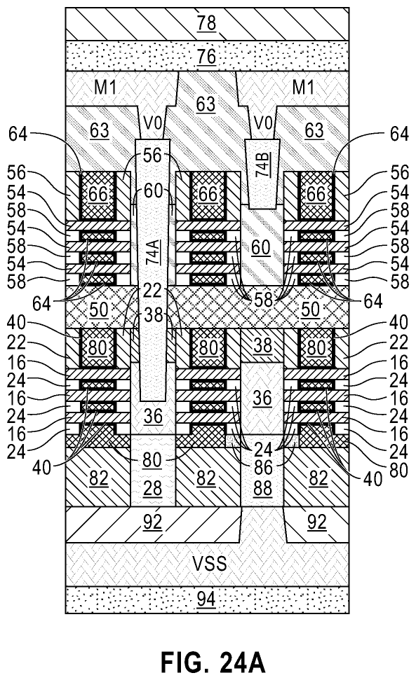

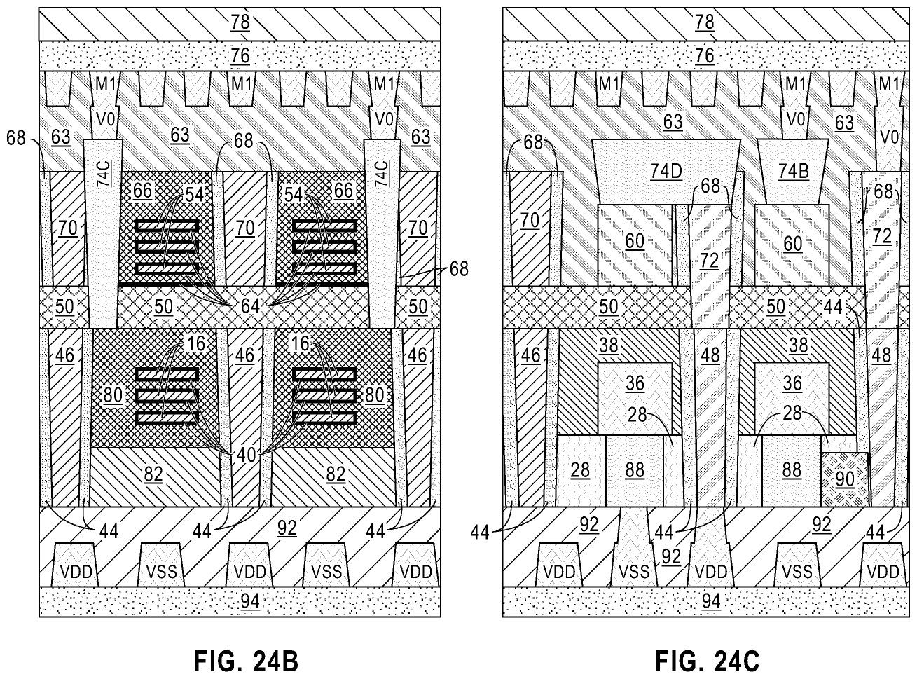

As stated above and in one aspect of the present application, a semiconductor device is provided. An embodiment of the semiconductor device of the present application is shown in FIGS. 24A, 24B and 24C. The semiconductor device includes a first FET having a first gate structure (including first gate dielectric layer 40 and first gate electrode 80) and a pair of first source/drain regions (i.e., first source/drain regions 36 shown in FIGS. 24A-24C) and a second FET stacked over the first FET. In the present application, the first FET can be referred to as a lower FET, while the second FET can be referred to as an upper FET. The second FET has a second gate structure (including second gate dielectric layer 64 and second gate electrode 66) and a pair of second source/drain regions (i.e., second source/drain regions 60 shown in FIGS. 24A-24C). The semiconductor device further includes dielectric pillar 28 located beneath the first FET and directly contacting one of the first source/drain regions (i.e., the first source/drain region 36 located to the left of the middle first gate electrode 80 shown in FIG. 24A) of the pair of first source/drain regions, and a backside gate dielectric cap 82 located adjacent to the dielectric pillar 28. In the present application, the backside gate dielectric cap 82 directly contacts a surface of the first gate electrode 80 of the first gate structure. By recessing the first gate electrode 80 from the backside of the wafer, and forming backside gate dielectric cap 82, one can effectively prevent shorting between the backside source/drain contact structure 88 and first gate electrode 80, by effectively forming symmetric inner spacer 86 (this can't be achieved if the gate is not recessed). By forming dielectric pillar 28 surrounding a sacrificial placeholder structure 34, one enables backside self-aligned contact formation.

In embodiments of the present application and as illustrated in FIGS. 24A-24C, dielectric pillar 28 further includes a sidewall having a first portion that directly contacts a sidewall of first gate electrode 80 and a second portion that directly contacts a sidewall of backside gate dielectric cap 82. Such a configuration provides electrical isolation to a portion of first gate electrode 80 which extends beneath the bottommost first inner spacer 24.

In embodiments of the present application and as illustrated in FIGS. 24A-24C, dielectric pillar 28 has a height that is greater than a height of backside gate dielectric cap 82. This ensures that the first gate electrode 80 is isolated from first source/drain region 36 (see, for example, FIG. 24A, if the dielectric pillar 28 is lower than the backside gate dielectric cap 82, then the first gate electrode 80 shorts to the first source/drain regions 36).

In embodiments of the present application and as illustrated in FIGS. 24A-24C, the semiconductor device further includes backside source/drain contact structure 88 contacting the other first source/drain region (i.e., the first source/drain region 36 located to the right of the middle first gate electrode 80 shown in FIG. 24A) of the pair of first source/drain regions. This establishes a backside connection to the first source/drain regions 36 of the first FET.

In embodiments of the present application and as illustrated in FIGS. 24A-24C, the semiconductor device further includes asymmetric inner spacer 86 which separates backside source/drain contact structure 88 from the first gate electrode 80; the asymmetric inner spacer 86 is only present on a side of the first gate electrode 80 in which the backside source/drain contact structure 88 is present. The presence of the asymmetric inner spacer 86 prevents shorting which occurs when the backside source/drain contact structure 88 and first gate electrode 80 are in contact with each other. Note that the dielectric pillar 28 provides electrically isolation on the other side of the first gate electrode 80.

In embodiments of the present application and as illustrated in FIGS. 24A-24C, the semiconductor device further includes backside BEOL structure 94 located beneath the first FET and connected to backside source/drain contact structure 88 by a backside VSS power source (labeled as VSS in FIGS. 24A-24C; VDD power sources, labeled as VDD in FIGS. 24A-24C, are also shown). The backside VSS power source provides power to the first FET and provides electrical connection of the first FET to the backside BEOL structure 94.

In embodiments of the present application and as illustrated in FIGS. 24A-24C, the semiconductor device further includes shared frontside source/drain contact structure 74A contacting the first source/drain region (i.e., the first source/drain region 36 to the left of the middle first gate electrode 80 shown in FIG. 24A) of the pair of first source/drain regions that is located on dielectric pillar 28 and one of the second source/drain regions (i.e., the second source/drain region 60 to the left of the middle second gate electrode 66 shown in FIG. 24A) of the pair of second source/drain regions. The shared frontside source/drain contact structure 74A establishes frontside electrical connection of both the first FET and the second FET.

In embodiments of the present application and as illustrated in FIGS. 24A-24C, shared frontside source/drain contact structure 74A is connected to frontside BEOL structure 76 by a metal via, V0, and a metal line, M1. This connection permits the first FET and second FET to be electrically connected to the frontside BEOL structure 76.

In embodiments of the present application and as illustrated in FIGS. 24A-24C, the semiconductor device further includes frontside source/drain contact structure 74B contacting the other second source/drain region (i.e., second source/drain region 60 to the right of the middle gate structure) of the pair of second source/drain regions and connected to frontside BEOL structure 76 by one other metal via (the far right V0 shown in FIG. 24A) and at least one other metal line (far right M1 shown in FIG. 24A). This connection permits the second FET to be electrically connected to the frontside BEOL structure 76.

In embodiments of the present application and as illustrated in FIGS. 24A-24C, the semiconductor device further includes frontside shared first/second gate electrode contact structure 74C contacting both first gate electrode 80 of the first gate structure, and second gate electrode 66 of the second gate electrode and connected to frontside BEOL structure 76 by yet another metal via and a yet another metal line (see, for example, the V0 and M1 shown in FIG. 24B). This establishes a combined gate electrode connection to the frontside BEOL structure 76.

In embodiments of the present application and as illustrated in FIGS. 24A-24C, the second gate structure includes second gate electrode 66. In embodiments, the second gate electrode 66 is composed of a compositionally different work function metal than the first gate electrode 80. This aspect evidence that the present application provides stacked FETs having different work function metals which is difficult to achieve utilizing conventional stacked FET processes.

In embodiments of the present application and as illustrated in FIGS. 24A-24C, the first gate structure (i.e., first gate dielectric layer 40 and first gate electrode 80) is wrapped around a portion of at least one first semiconductor channel material nanosheet 16 of a first nanosheet stack, and the second gate structure (i.e., second gate dielectric layer 64 and second gate electrode 66) is wrapped around a portion of at least one second semiconductor channel material nanosheet 54 of a second nanosheet stack. Nanosheet devices offer larger effective device width (Weff) per active footprint and better performance compared to FinFET, with a less complex photolithography strategy, leveraging Extreme Ultraviolet Lithography (EUV). Nanosheet devices provides better power-performance design point due to superior electrostatic control in such devices, where the gate surrounds the channel on all sides versus only three sides in FinFET. Therefore, in the future generation technology, nanosheets should be foundation device structure for stacked transistors.

In embodiments of the present application and as illustrated in FIGS. 24A-24C, the first FET is spaced apart from the second FET by bonding dielectric layer 50. Bonding dielectric layer 50 permits separation of the stacked FETs and allows for using different work function metals for the gate electrodes of the stacked FETs.

In embodiments of the present application and as illustrated in FIGS. 24A-24C, the semiconductor device can further include a first gate cut structure (combination of elements 44/46 to be defined below) located adjacent to the first FET, and a second gate cut structure (combination of elements 68/70 to be defined herein below) located adjacent to the second FET. Gate cut structure are used to cut the gate structures between different active device areas and provide isolation between the cut gates. In the present application, a second gate cut structure is stacked above a first gate cut structure.

In embodiments of the present application and as is illustrated in FIGS. 24A-24C, the first gate cut structure includes first outer dielectric material liner 44 encasing first inner core dielectric material 46, and the second gate cut structure includes second outer dielectric material liner 68 encasing second inner core dielectric material 70. Gate cut structures that are composed of such bi-layered dielectric materials are more robust and provide greater electrical isolation than gate cut structures that are composed of a single dielectric material.

In embodiments of the present application and as is illustrated in FIGS. 24A-24C, the first gate structure and the second gate structure are spaced apart by bonding dielectric layer 50.

In embodiments of the present application and as is illustrated in FIGS. 24A-24C, the semiconductor device further includes a frontside/backside deep via structure (combination of first deep via structure 48 and second deep via structure 72) having a first end electrically connected to one of the second source/drain regions 60 of the pair of second source/drain regions by frontside second gate source/drain contact structure 74D, and a second end electrically connected to backside BEOL structure 94 by a VDD power source (See, for example, FIG. 24C). This connection electrically connects the second FET to the backside BEOL structure 94.

In embodiments of the present application and as is illustrated in FIGS. 24A-24C, the frontside/backside deep via structure (combination of first deep via structure 48 and second deep via structure 72) has an upper via portion encased in second outer dielectric material liner 68, a lower portion that is encased in first outer dielectric material liner 44, and a middle portion that is encased in bonding dielectric layer 50 that is located between the first FET and the second FET. This dielectric material encasement electrically isolates the frontside/backside deep via structure from shorting other elements of the stacked FETs.

In embodiments of the present application and as is illustrated in FIGS. 24A-24C, the first FET and the second FET are present in a first active area, and wherein at least one other second FET stacked above at least one other first FET is located in a second active area that is spaced apart from the first active area, wherein one first source/drain region 36 of the at least one other first FET (see far right-hand side of FIG. 24C) is electrically connected to frontside BEOL structure 76 by a combination of backside source/drain contact structure 88, backside metal connector 90, a frontside/backside deep via structure, a metal via and a metal line (i.e., far right V0/M1 combination shown in FIG. 24C). This provides electrically connection of the at least one other first FET with the frontside BEOL structure 76.

In embodiments of the present application and as is illustrated in FIG. 24C, backside metal connector 90 directly contacts a sidewall of a lower portion of the frontside/backside deep via structure, and a sidewall of the backside source/drain contact structure.

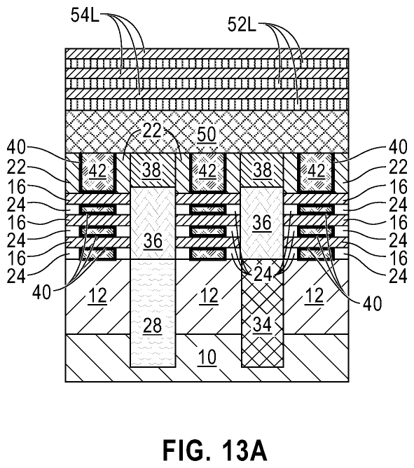

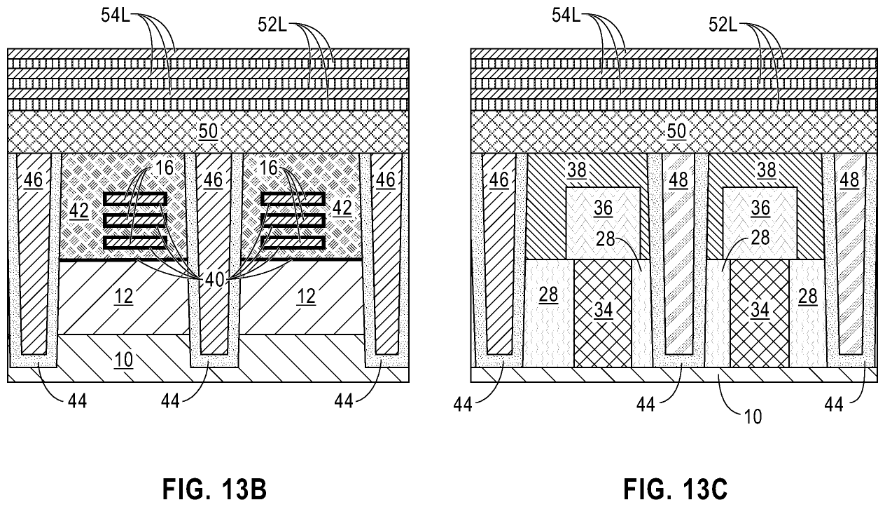

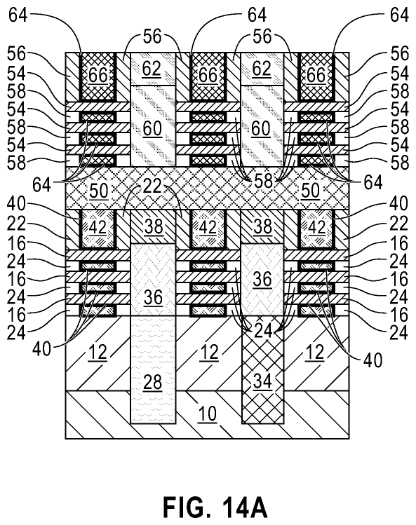

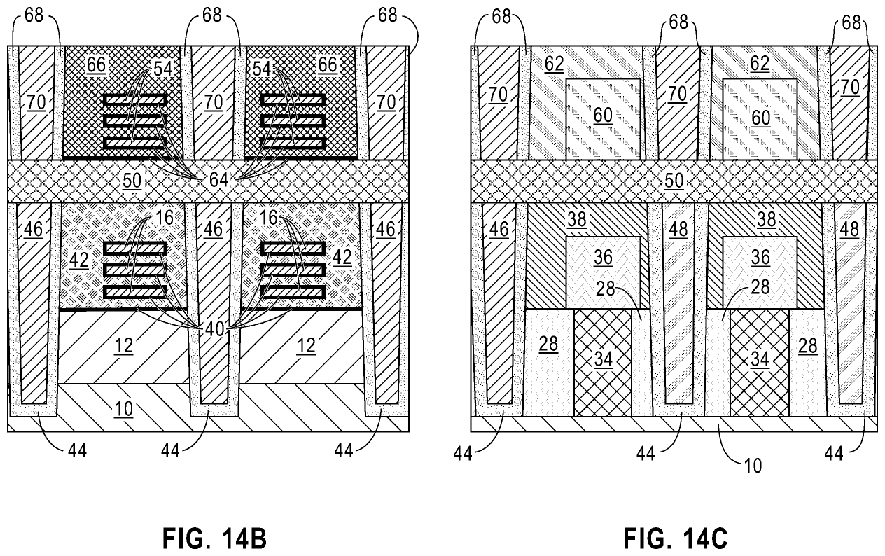

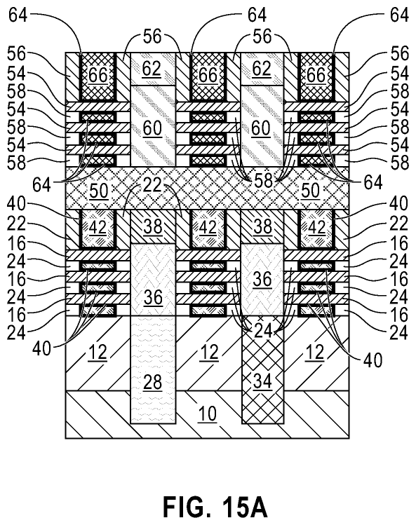

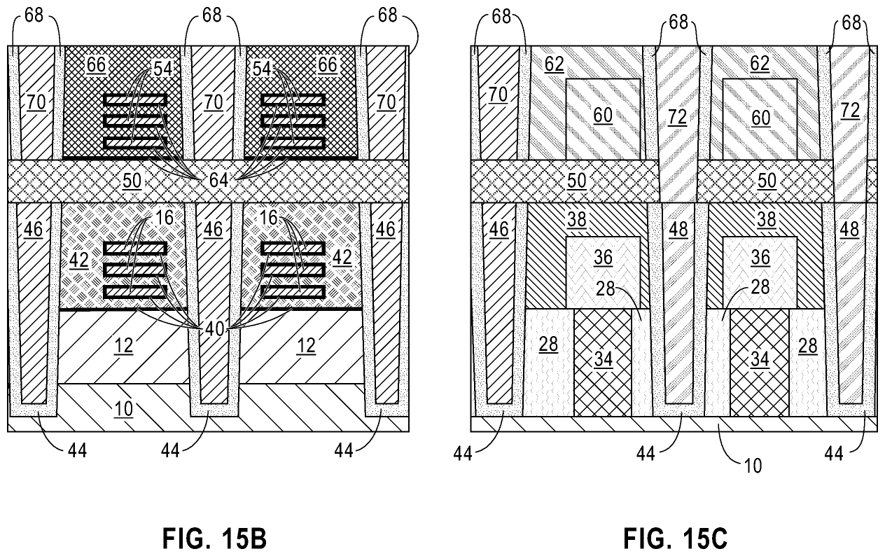

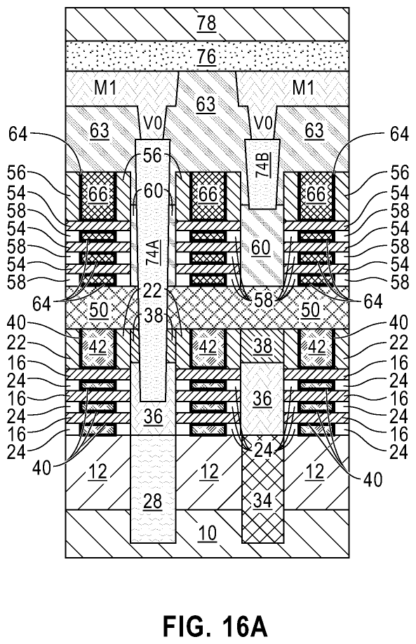

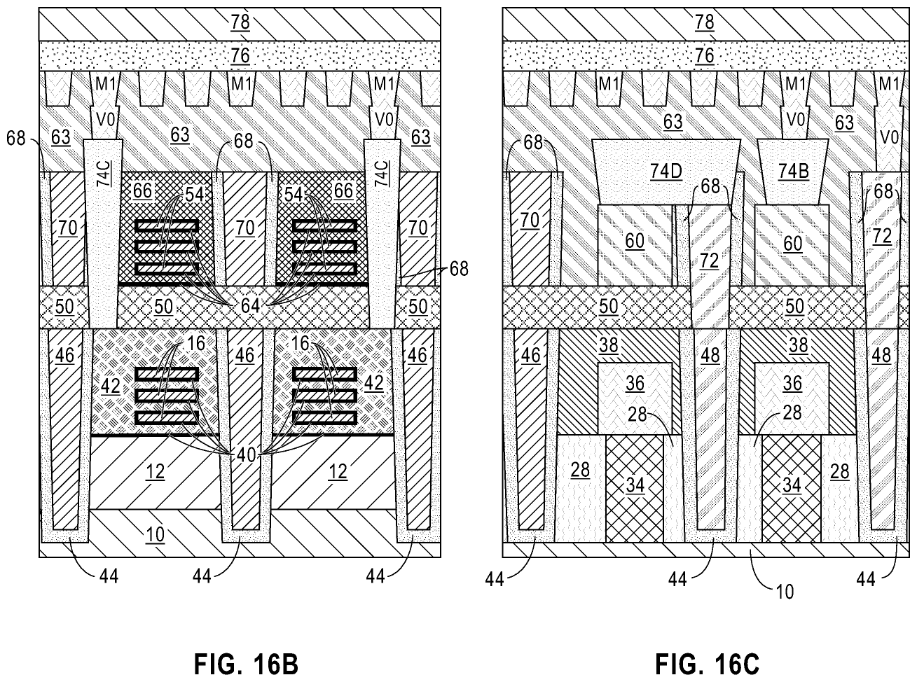

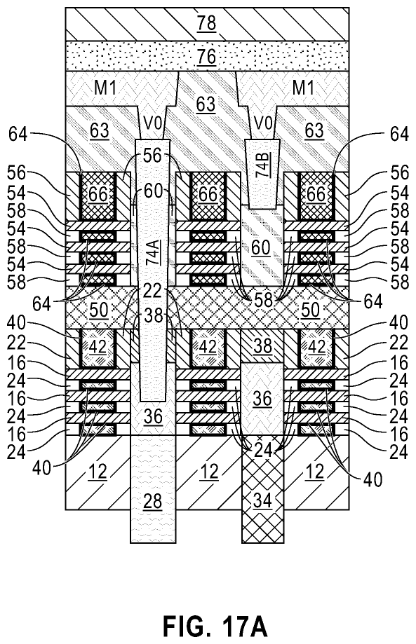

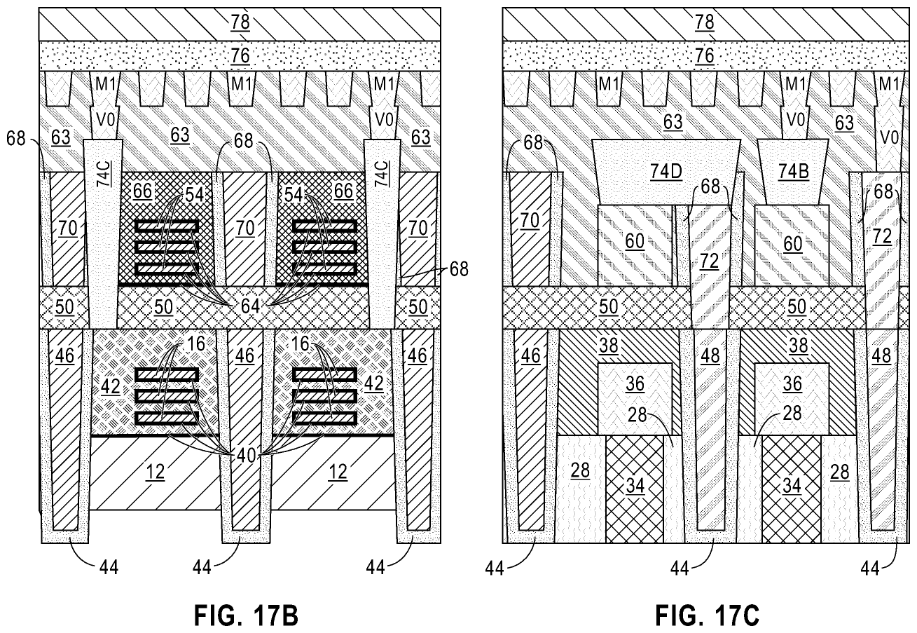

In another aspect of the present application as will be described in FIGS. 2A-24C, a process is provided that includes forming at least one precursor first gate structure including a first gate dielectric layer located on a surface of at least one first semiconductor channel material, and a first gate placeholder structure on the first gate dielectric layer, wherein the at least one precursor first gate structure includes a pair of first source/drain regions, and wherein a dielectric pillar is located beneath one of the first source/drain regions of the pair of first source/drain regions, and a sacrificial placeholder structure is located beneath the other first source/drain region of the pair of first source/drain regions. FIGS. 2A-12C form the at least one precursor first gate structure. Next, at least one second gate structure is formed above the at least one precursor first gate structure, the at least one second gate structure includes a second gate dielectric layer located on a surface of at least one second semiconductor channel material, a second gate electrode located on the second gate dielectric layer, and a pair of second source/drain regions; see FIGS. 13A-14C. At least frontside contact structures and a frontside BEOL structure are then formed on top of the second gate structure; See FIGS. 15A-16C. Next, the first gate placeholder structure is replaced from a backside of the device with a first gate electrode, wherein the replacing converts the at least one precursor first gate structure into at least one first gate structure, and then the sacrificial placeholder structure is replaced with a backside source/drain contact structure. These steps are shown in FIGS. 17A-23C. Next, at least VSS power supplies and VDD power supplies and a backside BEOL structure are formed; see FIGS. 24A-24C. Stacked FETs are formed by this process. The process of the present application optimizes the thermal budget without negatively impacting the frontside and/or backside contact structures.

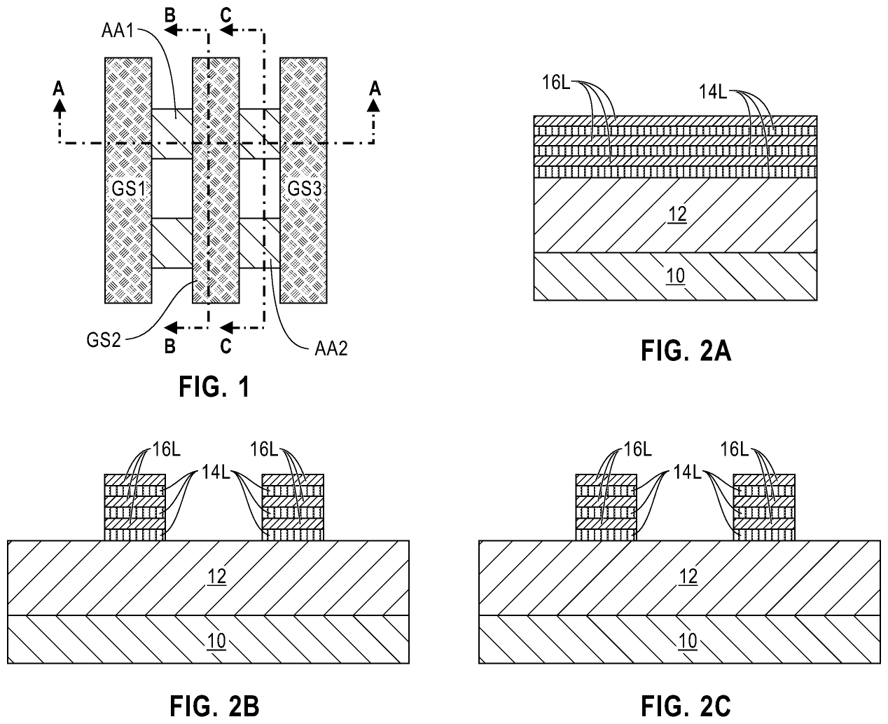

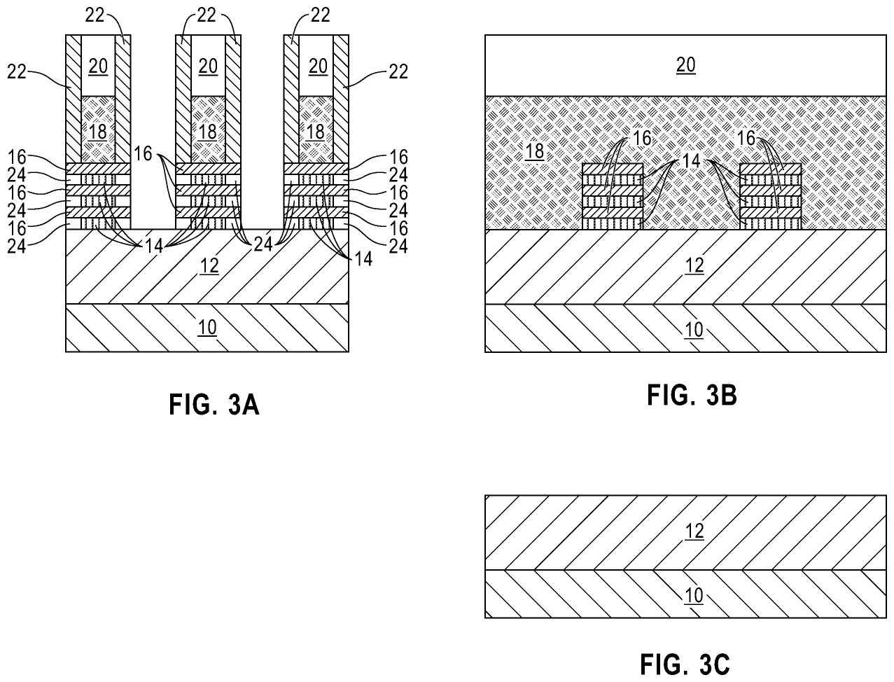

These and other aspects of the present application will now be described in greater detail by first referring to FIG. 1. Notably, FIG. 1 illustrates an exemplary semiconductor device layout that can be employed in accordance with an embodiment of the present application. The semiconductor device layout includes a plurality of active areas, AA, oriented along a first direction, and a plurality of functional gate structures, e.g., GS1, GS2 and GS3, that are oriented in a second direction which is perpendicular to the first direction; in the drawing cut A-A, cut B-B and cut C-C are shown. By way of an example, three functional gate structures, GS1, GS2 and GS3, and two active areas, AA1 and AA2, are shown. Cut A-A is through a length-wise direction of one of the active areas, e.g., AA1 and through each of GS1, GS2 and GS3, cut B-B is through a length-wise direction of one of the gate structures, e.g., GS2, and through two active areas, AA1 and AA2, and cut C-C is located in between two neighboring gate structures, e.g., GS2 and GS3, and it passes through source/drain (S/D) regions of the two neighboring gate structures and spans through two active areas, AA1 and AA2. In the present application, each of FIGS. 2A, 3A, . . . 24A is through cut A-A, while each of FIGS. 2B, 3B, . . . 24B is through cut B-B, and each of FIGS. 2C, 3C, . . . 24C is through cut C-C.

Reference is now made to FIGS. 2A, 2B and 2C, which illustrate an exemplary semiconductor structure that can be employed in the present application. The illustrated semiconductor structure includes a semiconductor substrate 10, an etch stop layer 12, and at least one first patterned material stack (two of which are shown by way of one example in FIGS. 2B and 2C). Each first patterned material stack includes alternating first sacrificial semiconductor material layers 14L and first semiconductor channel material layers 16L.

The semiconductor substrate 10 is composed of a first semiconductor material. The term “semiconductor material” is used throughout the present application to denote a material having semiconducting properties. Examples of first semiconductor materials that can be used in the present application in providing the semiconductor substrate 10 include, but are not limited to, silicon (Si), a silicon germanium (SiGe) alloy, a silicon germanium carbide (SiGeC) alloy, germanium (Ge), III/V compound semiconductors or II/VI compound semiconductors. The semiconductor substrate 10 is typically composed of one of the above first semiconductor materials. In one example, the semiconductor substrate 10 is composed of Si.

The etch stop layer 12 of the exemplary semiconductor structure illustrated in FIGS. 2A-2C can be composed of a dielectric material such as, for example, silicon dioxide and/or boron nitride.

As mentioned above, each first patterned material stack includes alternating first sacrificial semiconductor material layers 14L and first semiconductor channel material layers 16L. In some embodiments and as is illustrated in FIGS. 2A-2C, there an equal number of first sacrificial semiconductor material layers 14L and first semiconductor channel material layers 16L. That is, each material stack can include ‘n’ number of first sacrificial semiconductor material layers 14L and ‘n’ number of first semiconductor channel material layers 16L, wherein n is an integer starting from one. By way of one example, each first patterned material stack includes three first sacrificial semiconductor material layers 14L and three first semiconductor channel material layers 16L.

Each first sacrificial semiconductor material layer 14L is composed of a second semiconductor material, while each first semiconductor channel material layer 16L is composed of a third semiconductor material that is compositionally different from the second semiconductor material. The second semiconductor material that provides each first sacrificial semiconductor material layer 14L, and the third semiconductor material that provides each first semiconductor channel material layer 16L can include one of the semiconductor materials mentioned above for the semiconductor substrate 10. In one example, each first sacrificial semiconductor material layer 14L is composed of a silicon germanium alloy having a germanium content from 20 atomic percent to 40 atomic percent, and each first semiconductor channel material layer 16L is composed of silicon. Other combinations of semiconductor materials are possible as long as the second semiconductor material is compositionally different from the third semiconductor material. In some embodiments, the third semiconductor material that provides each first semiconductor channel material layer 16L can provide high channel mobility for n-type field effect transistor (FET) devices. In other embodiments, the third semiconductor material that provides each first semiconductor channel material layer 16L can provide high channel mobility for p-type FET devices.

Each first sacrificial semiconductor material layer 14L can have a first thickness, and each first semiconductor channel material layer 16L can have a second thickness. In the present application, the first thickness can be equal to, greater than, or less than, the second thickness. The first sacrificial semiconductor material layers 14L and the first semiconductor channel material layers 16L have equal widths at this point of the process of the present application.

The exemplary semiconductor structure shown in FIGS. 2A-2C can be formed utilizing techniques well known to those skilled in the art. In one example, the exemplary semiconductor structure shown in FIGS. 2A-2C can be formed by depositing the etch stop layer 12 on the semiconductor substrate 10, depositing a first material stack of the alternating first sacrificial semiconductor material layers 14L and first semiconductor channel material layers 16L on the etch stop layer 12, and then patterning the as-deposited first material stack. The deposition of the etch stop layer 12 can include chemical vapor deposition (CVD), plasma enhanced chemical vapor deposition (PECVD), atomic layer deposition (ALD) or physical vapor deposition (PVD). The deposition of the first material stack can include CVD, PECVD or epitaxial growth. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

Patterning can include lithography and etching (dry etching and/or chemical wet etching). Dry etching can include, for example, reactive ion etching (RIE), ion beam etching (IBE), and plasma etching. Chemical wet etching includes the use of an appropriate chemical etchant that has a high etch rate for one material as compared to at least one another material.

Referring now to FIGS. 3A, 3B and 3C, there are illustrated the exemplary semiconductor structure shown in FIGS. 2A, 2B and 2C, respectively, after forming at least one first sacrificial gate structure 18 and at least one first gate spacer 22, nanosheet patterning of the at least one first patterned material stack to form at least one first nanosheet stack (three of which are shown by way of one example in FIG. 3A) including alternating first sacrificial semiconductor material nanosheets 14 and first semiconductor channel material nanosheets 16, recessing each first sacrificial semiconductor material nanosheet 14, and forming a first inner spacer 24 adjacent to each first sacrificial semiconductor material nanosheet 14 that has been recessed. In some embodiments, a first sacrificial hard mask 20 can be located on a surface of the first sacrificial gate structure 18. In other embodiments, the first sacrificial hard mask 20 can be omitted.

The least one first sacrificial gate structure 18 includes at least a sacrificial gate material. In some embodiments, the least one first sacrificial gate structure 18 can also include a sacrificial gate dielectric material. In such embodiments, the sacrificial gate dielectric material would be located beneath the sacrificial gate material. The optional sacrificial gate dielectric material can be composed of a dielectric material such as, for example, silicon dioxide. The sacrificial gate material can be composed of, for example, polysilicon, amorphous silicon, amorphous silicon germanium or amorphous germanium. The first sacrificial hard mask 20 is composed of a hard mask material such as, for example, silicon nitride.

The at least one first sacrificial gate structure 18 including the optional first sacrificial hard mask 20 can be formed by depositing the optional sacrificial gate dielectric material, depositing the sacrificial gate material and, depositing, if the first sacrificial hard mask 20 is present, the hard mask material and thereafter subjecting the as-deposited material layers to a patterning process. Patterning includes lithography and etching as defined above. Each first sacrificial gate structure 18 straddles a portion of the at least one first patterned material stack. The term “straddles” denotes that one material layer is located on a topmost surface and opposing sidewall surfaces of another material layer.

The first gate spacer 22, which is present along a sidewall of the at least one first sacrificial gate structure 18 and if present, the first sacrificial hard mask 20, can be composed of a dielectric spacer material including, but not limited to, silicon dioxide, SiN, SiBCN, SiOCN or SiOC. The first gate spacer 22 can be formed by deposition of the dielectric spacer material, followed by a spacer etch.

Next, the first patterned material stack is subjected to nanosheet patterning to form at least one first nanosheet stack (three of which are shown by way of one example in FIG. 3A). The at least one first nanosheet stack includes alternating first sacrificial semiconductor material nanosheets 14 (i.e., remaining non-etched portions of the each first sacrificial semiconductor material layer 14L) and first semiconductor channel material nanosheets 16 (i.e., remaining non-etched portions of the each first semiconductor channel material layer 16L). The nanosheet patterning utilizes the at least one first sacrificial gate structure 18, the optional first sacrificial hard mask 20 and the first gate spacer 22 that is present along at least the sidewalls of the at least one first sacrificial gate structure 18 as a combined etch mask. An etch such as, for example, RIE, is then employed to remove portions of the first patterned material stack that are not protected by the combine etch mask. Immediately after nanosheet patterning, the first sacrificial semiconductor material nanosheets 14 and the first semiconductor channel material nanosheets 16 have a same width.

Each first sacrificial semiconductor material nanosheet 14 is then recessed utilizing a lateral etching process that removes an end portion of each first sacrificial semiconductor material nanosheet 14. After recessing, the width along cut A-A shown in FIG. 3A of each first sacrificial semiconductor material nanosheet 14 is less than the original width of each first sacrificial semiconductor material nanosheet 14. The lateral etch forms indentations within the at least one first nanosheet stack. First inner spacer 24 is then formed into each indentation. The first inner spacer 24 is composed of one of the dielectric spacer materials mentioned above for the first gate spacer 22. The dielectric spacer material that provides each first inner spacer 24 can be compositionally the same as, or compositionally different from, the dielectric spacer material that provides the first gate spacer 22.

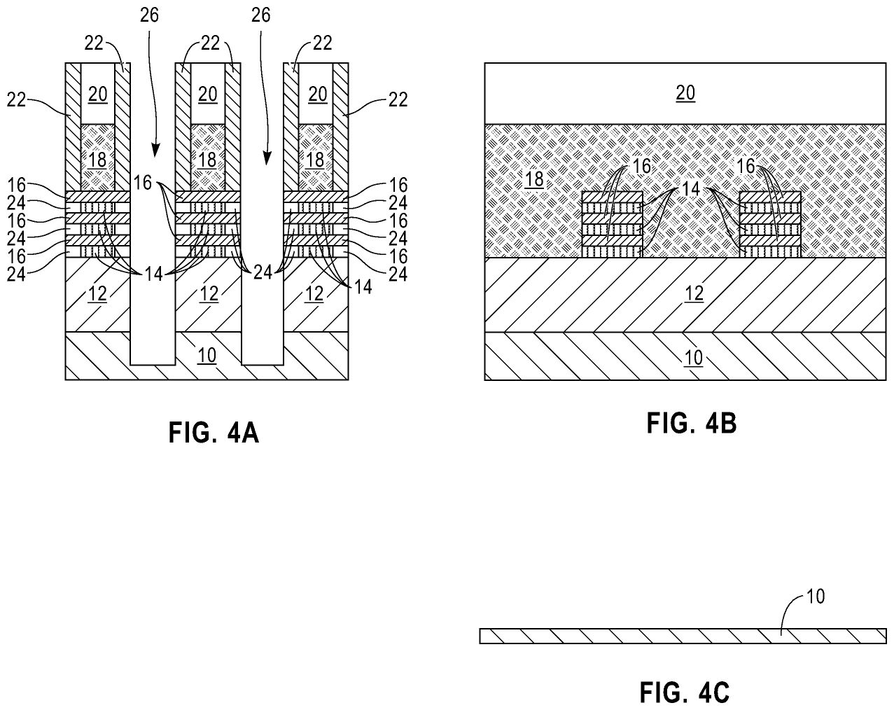

Referring now to FIGS. 4A, 4B and 4C, there are illustrated the exemplary semiconductor structure shown in FIGS. 3A, 3B and 3C, respectively, after forming a sacrificial placeholder recess 26 within the semiconductor substrate 10 utilizing the combined etch mask mentioned above and etching. The term “sacrificial placeholder recess” is used in the present application to define an etched region of the semiconductor substrate 10 in which a sacrificial structure will be subsequently formed. In the illustrated embodiment, two sacrificial placeholder recesses 26 are formed as is shown in FIG. 4A. The etch removes portions of the etch stop layer 12 and portions of the semiconductor substrate 10 that are not protected by the combined etch mask. The etch does not extend entirely through the semiconductor substrate 10. Instead, the etch stops on a sub-surface of the semiconductor substrate 10. The term “sub-surface” is used throughout the present application to denote a surface of a material layer that is located between a topmost surface of the material layer and a bottommost surface of the material layer. The etch that provides the sacrificial placeholder recess 26 can include a timed RIE process.

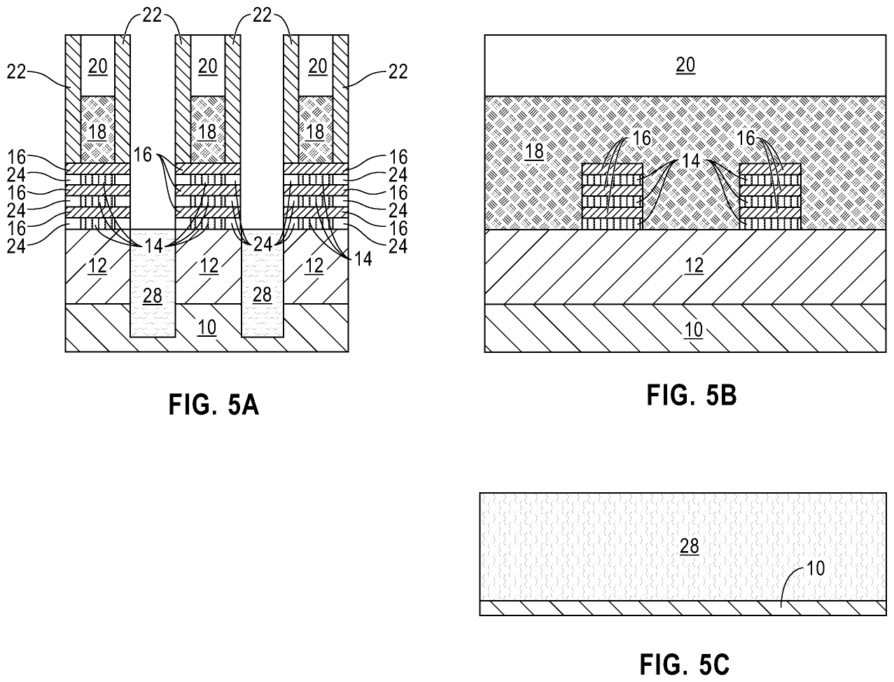

Referring now to FIGS. 5A, 5B and 5C, there are illustrated the exemplary semiconductor structure shown in FIGS. 4A, 4B and 4C, respectively, after forming a dielectric pillar 28 in each sacrificial placeholder recess 26. The dielectric pillar 28 can be formed by first depositing a dielectric material and thereafter subjecting the as-deposited dielectric material to a recess etch. The dielectric pillar 28 is composed of a dielectric material that is compositionally different from the etch stop layer 12 and the dielectric spacer material(s) used in providing the first gate spacer 22 and the first inner spacer 24. Exemplary dielectric materials that can be used in providing the dielectric pillar 28 include, but are not limited to, SiC or SiOC. The dielectric pillar 28 has a bottommost surface that directly contacts the sub-surface of the semiconductor substrate 10 and a topmost surface that can be, but not necessarily, coplanar with a topmost surface of the etch stop layer 12.

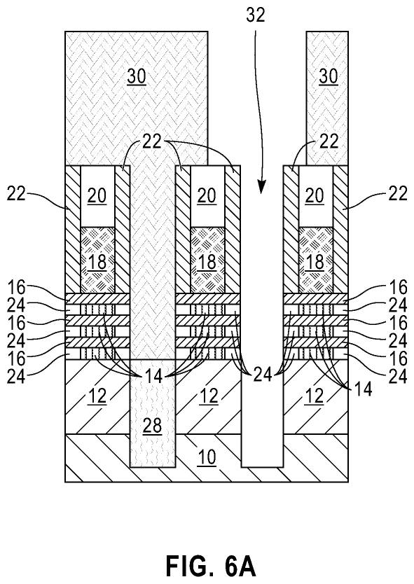

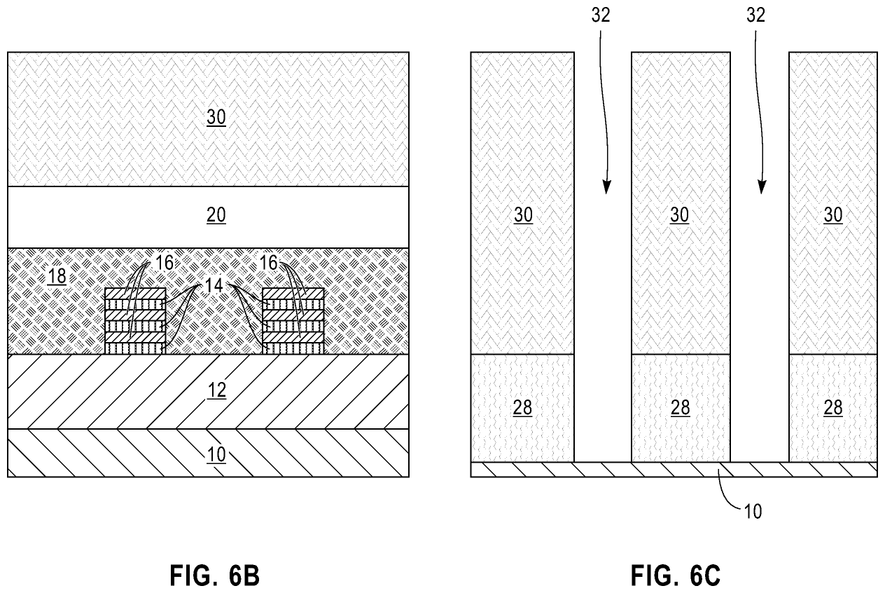

Referring now to FIGS. 6A, 6B and 6C, there is illustrated the exemplary semiconductor structure shown in FIGS. 5A, 5B and 5C, respectively, after removing at least one of the dielectric pillars 28; not all the dielectric pillars 28 are removed during this step of the present application. In the illustrated embodiment, the dielectric pillar 28 is removed in the source/drain regions between GS2 and GS3 illustrated in FIG. 1. Dielectric pillar removal includes forming a patterned organic planarization layer (OPL) 30 that has openings on the exemplary structure shown in FIGS. 5A-5C. The patterned OPL 30 can be formed by deposition of an OPL material, followed by lithography and etching. After forming the patterned OPL 30, another etch such as, RIE, is used to remove dielectric pillars 28 that are not protected by the patterned OPL 30. Openings 32 are formed as shown in FIGS. 6A and 6C. Note that in the source/drain region shown in FIG. 6C, this etch removes portions of the dielectric pillar 28 that is present in that area of the structure.

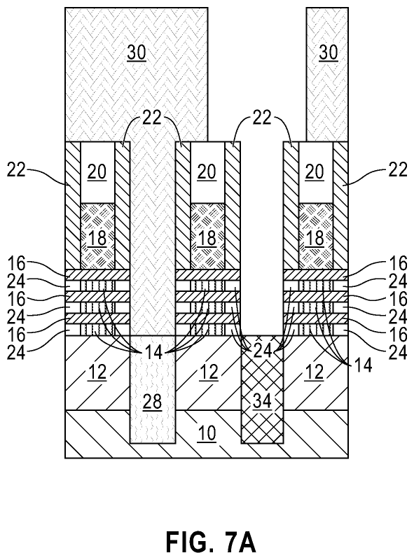

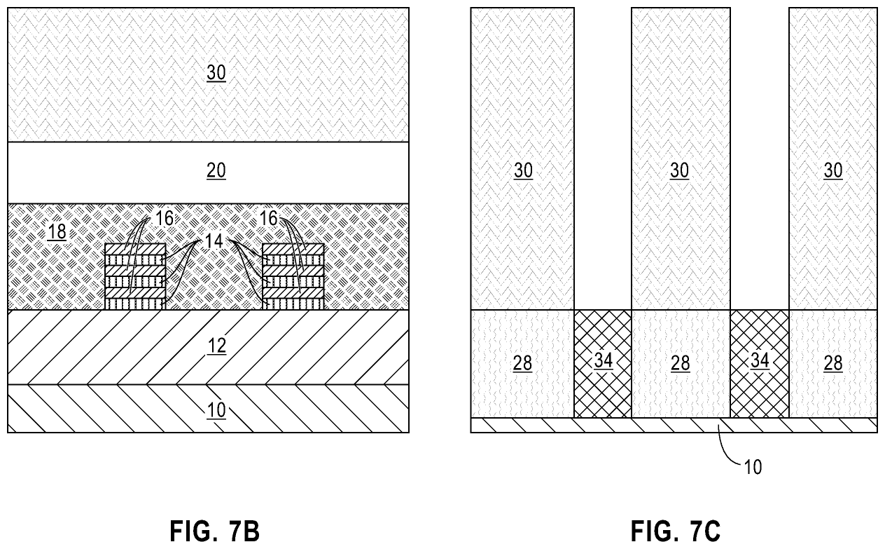

Referring now to FIGS. 7A, 7B and 7C, there are illustrated the exemplary semiconductor structure shown in FIGS. 6A, 6B and 6C, respectively, after forming a sacrificial placeholder structure 34 in the area previously occupied by the removed at least one dielectric pillar 28 (i.e., within openings 32). The sacrificial placeholder structure 34 can be formed by first depositing a sacrificial material and thereafter subjecting the as-deposited sacrificial material to a recess etch. The sacrificial placeholder structure 34 is composed of a sacrificial material that is compositionally different from the etch stop layer 12 and each dielectric spacer material used in providing the first gate spacer 22 and the first inner spacer 24 as well as the dielectric material that provides the dielectric pillar 28. Exemplary sacrificial materials that can be used as the sacrificial placeholder structure 34 include, but are not limited to, SiGe, AlOₓ and TiOₓ. The sacrificial placeholder structure 34 has a bottommost surface that directly contacts the sub-surface of the semiconductor substrate 10 and a topmost surface that can be, but not necessarily, coplanar with a topmost surface of the etch stop layer 12.

After forming the sacrificial placeholder structure 34, the patterned OPL 30 is removed from the structure. The patterned OPL 30 can be removed utilizing any material removal process that selectively removes the OPL material that provides the patterned OPL 30.

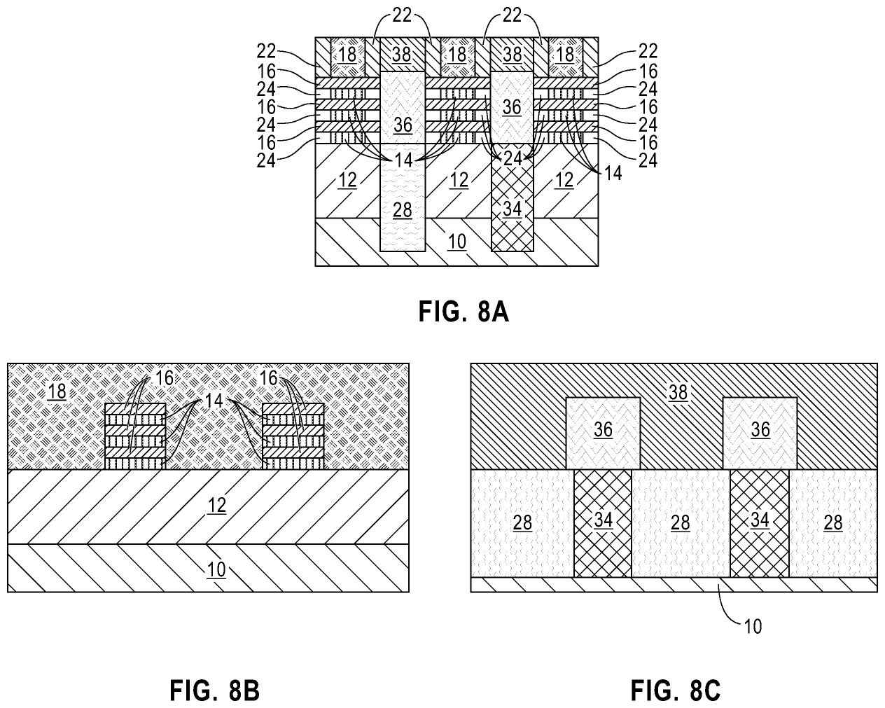

Referring now to FIGS. 8A, 8B and 8C, there are illustrated the exemplary semiconductor structure shown in FIGS. 7A, 7B and 7C, respectively, after forming first source/drain regions 36 and a first frontside interlayer dielectric (ILD) layer 38. In the present application, each first sacrificial gate structure 18 will include a pair of first source/drain regions 36; this is illustrated by the middle first sacrificial gate structure 18 shown in FIG. 8A.

The first source/drain regions 36 are typically formed by an epitaxial growth process, as defined above. The first source/drain regions 36 extend outward from a sidewall of each first semiconductor channel material nanosheet 16. Within each pair of first source/drain regions 36 (and as illustrated in FIG. 8A), one of the first source/drain regions 36 is located on an upper surface of the dielectric pillar 28, while another of the first source/drain regions 36 is located on an upper surface of the sacrificial placeholder structure 34. Each of the first source/drain regions 36 is composed of a fourth semiconductor material and a first dopant. As used herein, a “source/drain” region can be a source region or a drain region depending on subsequent wiring and application of voltages during operation of the transistor. The fourth semiconductor material that provides each first source/drain region 36 is composed of one of the semiconductor materials mentioned above for the semiconductor substrate 10. The fourth semiconductor material that provides the first source/drain regions 36 can be compositionally the same, or compositionally different from, the third semiconductor material that provides each first semiconductor channel material nanosheet 16. The fourth semiconductor material that provides each first source/drain region 36 is however compositionally different from the second semiconductor material that provides each first sacrificial semiconductor material nanosheet 14. The first dopant that is present in the first source/drain regions 36 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each first source/drain region 36 can have a dopant concentration of from 4×10²⁰ atoms/cm³ to 3×10²¹ atoms/cm³.

The first frontside ILD layer 38 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The first frontside ILD layer 38 can be formed by a deposition process including, but not limited to, CVD, PECVD or spin-on coating. A planarization process such as, for example, chemical mechanical polishing (CMP) follows the deposition process. The planarization process removes the first sacrificial hard mask 20 (if the same is present) and an upper portion of each first gate spacer 22. The at least one first sacrificial gate structure 18 is physically exposed after this planarization process has been performed. Note that the first frontside ILD layer 38 is formed adjacent to, and on top of, each first source/drain region 36.

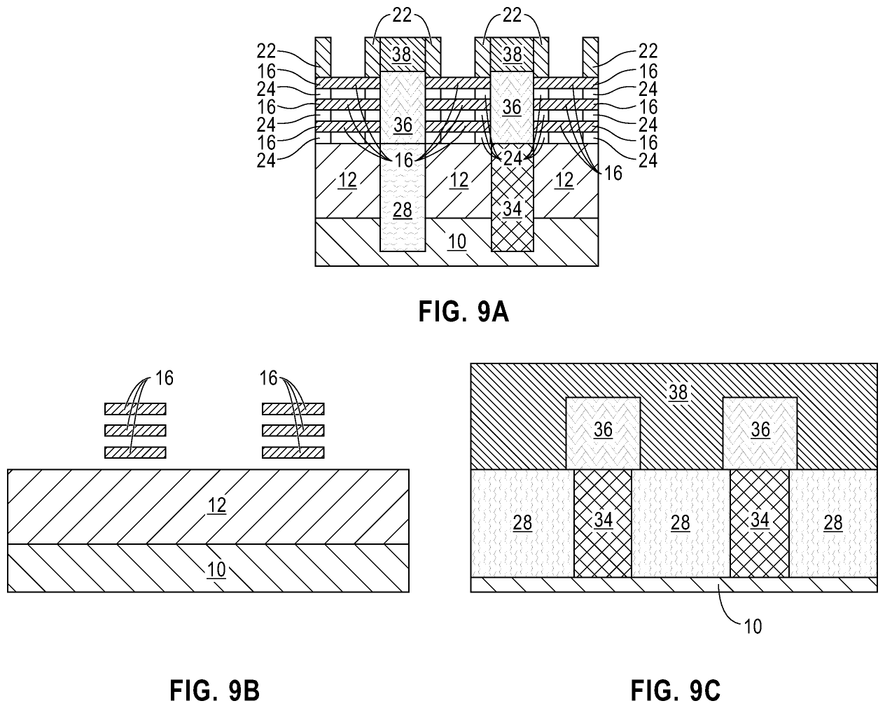

Referring now to FIGS. 9A, 9B and 9C, there are illustrated the exemplary semiconductor structure shown in FIGS. 8A, 8B and 8C, respectively, after removing the at least one first sacrificial gate structure 18, and each first sacrificial semiconductor nanosheet 14 to suspend a portion of each first semiconductor channel material nanosheet 16. The physically exposed at least one first sacrificial gate structure 18 is removed utilizing any material removal process such as, for example, etching, which is selective in removing the at least one first sacrificial gate structure 18. The removal of the at least one first sacrificial gate structure 18 reveals an underlying first nanosheet material stack. Next, each first sacrificial semiconductor material nanosheet 14 is removed utilizing any material removal process such as, for example, etching, which is selective in removing the first sacrificial semiconductor material nanosheets 14.

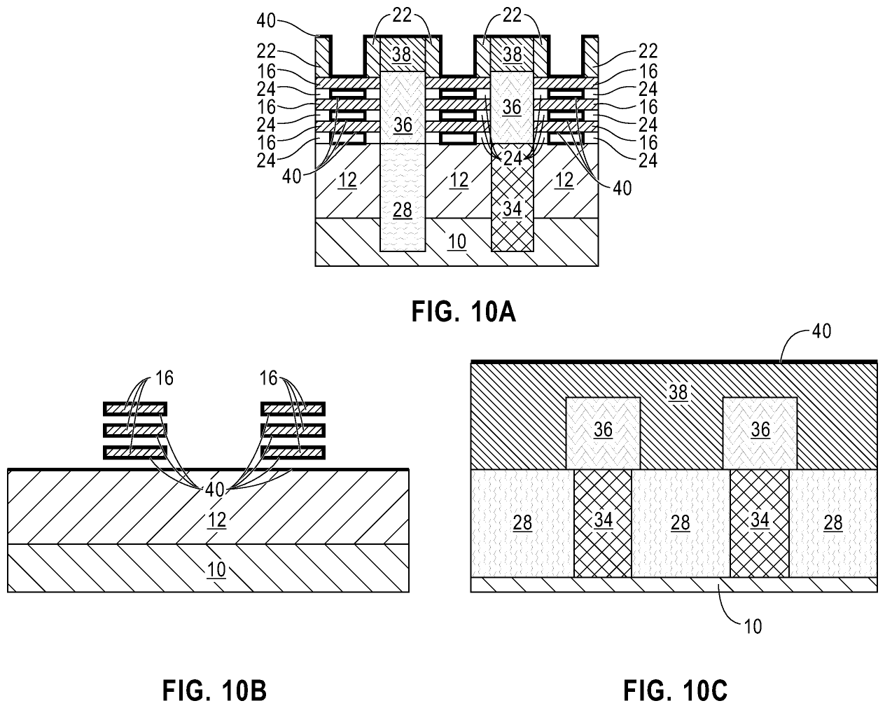

Referring now to FIGS. 10A, 10B and 10C, there are illustrated the exemplary semiconductor structure shown in FIGS. 9A, 9B and 9C, respectively, after forming a first gate dielectric layer 40 wrapped around the suspended portion of each first semiconductor channel material nanosheet 16. The first gate dielectric layer 40 is also formed along the sidewalls of the first gate spacer 22 and first inner spacer 24 as well as atop the first gate spacer 22 and the first frontside ILD layer 38. The first gate dielectric layer 40 is composed of a first gate dielectric material that has a dielectric constant of greater than 4.0. Illustrative examples of first gate dielectric materials that can be used in providing the first gate dielectric layer 40 include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The first gate dielectric material can further include dopants such as lanthanum (La), aluminum (Al) and/or magnesium (Mg). The first gate dielectric layer 40 can be formed by a deposition process such as, for example, CVD, PECVD or ALD.

In some embodiments of the present application, a dielectric anneal step can now be performed. In other embodiments of the present application, the dielectric anneal step can be omitted. When performed, the dielectric anneal reduces the defects that are present in the first gate dielectric layer 40. The dielectric anneal step can be performed in an ambient such as, for example, helium, argon, and/or neon. The dielectric anneal step can be performed at a temperature from 700° C. to 1000° C.

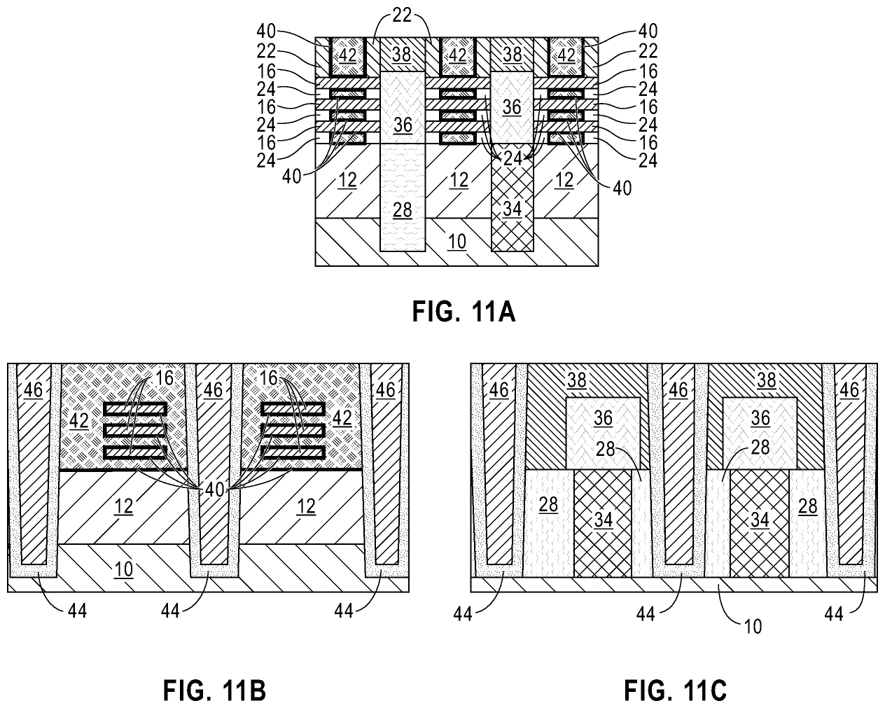

Referring now to FIGS. 11A, 11B and 11C, there are illustrated the exemplary semiconductor structure shown in FIGS. 10A, 10B and 10C, respectively, after forming a first gate placeholder structure 42 on the first gate dielectric layer 40 and forming first gate cut structures, each first gate cut structure including a first inner core dielectric material 46, and a first outer dielectric material liner 44. The first gate placeholder structure 42 can be composed of one of the sacrificial gate materials mentioned above and it can also include a diffusion barrier liner such as, for example, TaN or TiN. The first gate placeholder structure 42 can be formed by deposition, followed by a planarization process. The planarization process removes any sacrificial gate material, diffusion barrier material, and first gate dielectric layer 40 that is located on top of the first frontside ILD layer 38. At this point of the present application, precursor first gate structures are formed that include the first gate dielectric layer 40 and the first gate placeholder structure 42.

First gate cut structures are then formed, which extend upward from a sub-surface of the semiconductor substrate 10; the first gate cut structures have a topmost surface that is typically coplanar with a topmost surface of each of the first gate placeholder structure 42 and the first frontside ILD layer 38. The first gate cut structures are formed by first forming gate cut trenches by lithography and etching. A first outer dielectric material layer composed a first cut gate liner dielectric material is first formed into each gate cut trench by a first deposition process such as, for example, CVD, PECVD, or ALD. The as-deposited first outer dielectric material layer lines the sidewalls of each gate cut trench and is located on top of the first gate placeholder structure 42 and the first frontside ILD layer 38. A first inner core dielectric is then formed by a second deposition process such as, for example, CVD, PECVD or ALD, on the as-deposited first outer dielectric material layer. A planarization process is then used to remove any first inner core dielectric and first cut gate liner dielectric material that is present outside of the gate cut trenches. The remaining first outer dielectric material layer that is present in each gate cut trench provides the first outer dielectric material liner 44, while the remaining first inner core dielectric that is present in each gate cut trench provides the first inner core dielectric material 46.

The first cut gate liner dielectric material is composed of a dielectric material that is compositionally different from the first inner core dielectric. In one embodiment, the first cut gate liner dielectric material that provides the first outer dielectric material liner 44 is composed of silicon nitride, while the first inner core dielectric that provides the first inner core dielectric material 46 is composed of silicon dioxide. Other dielectric materials such as, for example, SiOCN, or SiBCN, can be used in providing the first outer dielectric material liner 44 and the first inner core dielectric material 46 as long as the dielectric used in forming the first outer dielectric material liner 44 and the first inner core dielectric material 46 are compositionally different and thus have different etch rates.

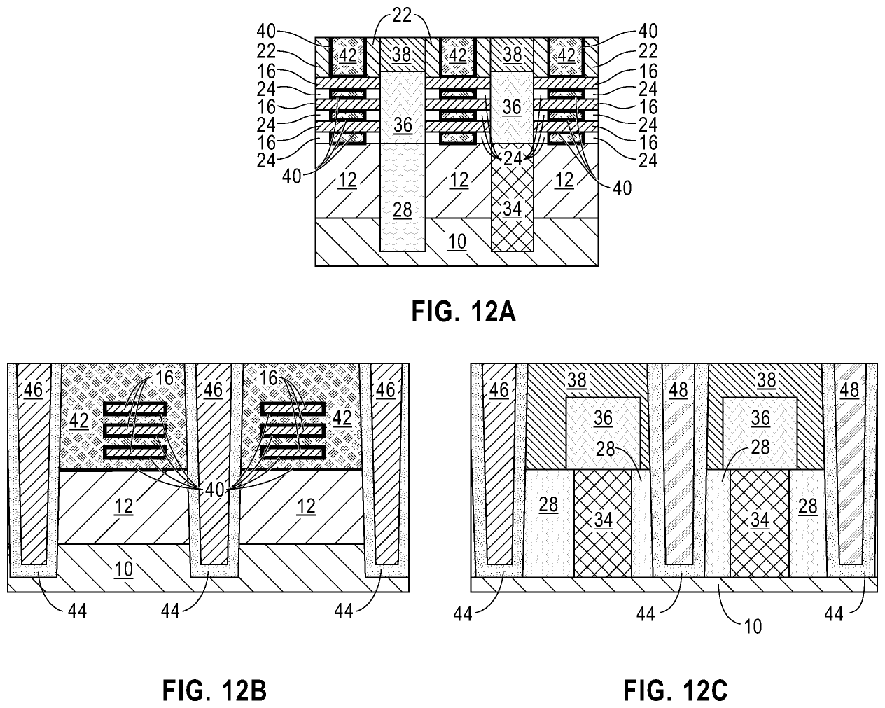

Referring now to FIGS. 12A, 12B and 12C, there is illustrated the exemplary semiconductor structure shown in FIGS. 11A, 11B and 11C, respectively, after removing the first inner core dielectric material 46 of some of the first gate cut structures and forming a first deep via structure 48 in each area that was previously occupied by a removed first inner core dielectric material 46. At this point of the present application, the first outer dielectric material liner 44 is located along the sidewall and bottom surface of the first deep via structure 48.

The removal the first inner core dielectric material 46 of some of the first gate cut structures includes forming a patterned mask (not shown) on the exemplary structure shown in FIGS. 11A-11C; the patterned mask has openings that physically some of the first gate cut structures. With this patterned mask in place, an etch is employed that selectively removes the first inner core dielectric material 46 relative to the first outer dielectric material liner 44. First deep via openings are formed. The patterned mask is now typically removed from the structure. The first deep via structure 48 is then formed into each of the first deep via openings utilizing a metallization process that includes filling (including deposition and planarization) each of the first deep via openings with at least a contact conductor material. The contact conductor material can include, for example, a conductive metal such as W, Cu, Al, Co, Ru, Mo, Os, Ir, Rh, or an alloy thereof.

Referring now to FIGS. 13A, 13B and 13C, there is illustrated the exemplary semiconductor structure shown in FIGS. 12A, 12B and 12C, respectively, after forming a bonding dielectric layer 50 and a second material stack of alternating second sacrificial semiconductor material layers 52L and second semiconductor channel material layers 54L. The bonding dielectric layer 50 is typically composed of a bonding dielectric oxide such as, for example, silicon dioxide. The bonding dielectric layer 50 is employed in the present application to electrically separate each stacked FET from one another. As mentioned above, the second material stack includes alternating second sacrificial semiconductor material layers 52L and second semiconductor channel material layers 54L. In some embodiments and as is illustrated in FIGS. 13A-13C, there is an equal number of second sacrificial semiconductor material layers 52L and second semiconductor channel material layers 54L. That is, the second material stack can include ‘m’ number of second sacrificial semiconductor material layers 52L and ‘m’ number of second semiconductor channel material layers 54L, wherein m is an integer starting from one. By way of one example, each second material stack includes three second sacrificial semiconductor material layers 52L and three second semiconductor channel material layers 54L. It is noted that “m” can be less than, equal to, or greater than “n”.

Each second sacrificial semiconductor material layer 52L is composed of a fifth semiconductor material, while each second semiconductor channel material layer 54L is composed of a sixth semiconductor material that is compositionally different from the fifth semiconductor material. It is noted that the fifth semiconductor material that provides each second sacrificial semiconductor material layer 52L can be compositionally the same as, or compositionally different from, the second semiconductor material that provides each first sacrificial semiconductor material layer 14L. It is noted that the sixth semiconductor material that provides each second semiconductor channel material layer 54L can be compositionally the same as, or compositionally different from, the third semiconductor material that provides each first semiconductor channel material layer 16L. The fifth semiconductor material that provides each second sacrificial semiconductor material layer 52L, and the sixth semiconductor material that provides each second semiconductor channel material layer 54L can include one of the semiconductor materials mentioned above for the semiconductor substrate 10. In one example, each second sacrificial semiconductor material layer 52L is composed of a silicon germanium alloy having a germanium content from 20 atomic percent to 40 atomic percent, and each second semiconductor channel material layer 54L is composed of silicon. Other combinations of semiconductor materials are possible as long as the fifth semiconductor material is compositionally different from the sixth semiconductor material. In some embodiments, the sixth semiconductor material that provides each second semiconductor channel material layer 54L can provide high channel mobility for n-type FET devices. In other embodiments, the sixth semiconductor material that provides each second semiconductor channel material layer 54L can provide high channel mobility for p-type FET devices. In embodiments, the first semiconductor channel material layers 16L mentioned above provides optimized mobility for a first conductivity type FET, while the second channel material layers 54L are optimized mobility for a second conductivity type FET, wherein the first conductivity FET is different in terms of conductivity than the second conductivity type FET.

Each second sacrificial semiconductor material layer 52L can have a third thickness, and each second semiconductor channel material layer 54L can have a fourth thickness. In the present application, the third thickness can be equal to, greater than, or less than, the fourth thickness.

The exemplary semiconductor structure shown in FIGS. 13A-13C can be formed utilizing techniques well known to those skilled in the art. In one example, the bonding dielectric layer 50 can be formed on the structure shown in FIGS. 12A-12C utilizing a deposition process such as, for example, CVD, PECVD, ALD or PVD. The second material stack can then be deposition on the as-deposited bonding dielectric layer 50. In other embodiments, a wafer bonding process can be employed. The wafer bonding process includes depositing the bonding dielectric layer 50 on a surface of handle substrate (not shown), and then forming the second material stack on the bonding dielectric layer 50. After forming the second material stack, the handle substrate can be removed from the structure including the bonding dielectric layer 50 and the second material stack and then the bonding dielectric layer 50 that is attached to the second material stack is brought into intimate contact with the structure shown in FIGS. 12A-12C. In some embodiments, the wafer bonding can include heating at temperature sufficient to cause bonding between the bonding oxide layer 50 and the structure shown in FIGS. 12A-12C.

Referring now to FIGS. 14A, 14B and 14C, there is illustrated the exemplary semiconductor structure shown in FIGS. 13A, 13B and 13C, respectively, after second device formation. Second device formation includes patterning of the second material stack to form at least one second patterned material stack. The patterning can include lithography and etching. Next, at least one at least one second sacrificial gate structure (not shown in the drawings) can be formed straddling a portion of the at least one patterned second material stack. The at least one second sacrificial gate structure includes materials as mentioned above for the at least one first sacrificial gate structure 18 and the at least one second sacrificial gate structure can be formed utilizing the process mentioned above in forming the at least one first sacrificial gate structure 18. An optional second sacrificial hard mask, not shown can also be formed. The optional second sacrificial hard mask is composed of one of the hard mask materials mentioned above for the first sacrificial hard mask 20.

Next, second gate spacers 56 are formed. The second gate spacers 56 are composed of one of the gate dielectric spacer materials mentioned above for the first gate spacers 22. The second gate spacers 56 can be formed by deposition of the gate spacer dielectric material, followed by a spacer etch.

The at least one second patterned material stack is the patterned to form at least one second nanosheet stack. This patterning step which includes an etch such as, for example, RIE, utilizes the at least one sacrificial gate structure, if present the second sacrificial hard mask, and the second gate spacers 56 as a combined etch mask. The at least on second nanosheet stack includes alternating second sacrificial semiconductor material nanosheets (remaining, i.e., non-etched portions of the second sacrificial semiconductor material layers 52L) and second semiconductor channel material nanosheets 54 (remaining, i.e., non-etched portions of the second semiconductor channel material layers 54L). The second sacrificial semiconductor material nanosheets are not shown in FIGS. 14A-14C since they are subsequently removed from the structure.

Second inner spacers 58 are then formed utilizing the same the same technique as mentioned above in forming the first inner spacers 22. Notably, the second inner spacer formation includes laterally etching, i.e., recessing, each second sacrificial semiconductor material nanosheet, and then filling the gaps created by this etch with a dielectric spacer material, as defined above. The filling includes deposition and a spacer etch.

Next, second source/drain regions 60 are formed by an epitaxial growth process, as defined above. The second source/drain regions 60 extend outward from a sidewall of each second semiconductor channel material nanosheet 54. Each second source/drain region 60 is located on a surface of the bonding dielectric layer 50. Each of the second source/drain regions 60 is composed of a seventh semiconductor material and a second dopant. The seventh semiconductor material that provides each second source/drain region 60 is composed of one of the semiconductor materials mentioned above for the semiconductor substrate 10. The seventh semiconductor material that provides the second source/drain regions 60 can be compositionally the same, or compositionally different from, the sixth semiconductor material that provides each second semiconductor channel material nanosheet 54. The seventh semiconductor material that provides each second source/drain region 60 is however compositionally different from the fifth semiconductor material that provides each second sacrificial semiconductor material nanosheet. The second dopant that is present in the second source/drain regions 60 can be of a same conductivity type, or a different conductivity type, than the first dopant that is present in the first source/drain regions 36. In the present application, it is possible to form stacked FET that are of a same conductivity type, or stacked FETs that are of different conductivity types.

Second frontside ILD layer 62 is then formed laterally adjacent to, and on top of, each of the second source/drain regions 60; the second frontside ILD layer 62 also contacts a surface of the bonding dielectric layer 50. The second frontside ILD layer 62 is composed of one of the dielectric materials mentioned above for the first frontside ILD layer 38. The second frontside ILD layer 62 can be formed by deposition, followed by a planarization process. The planarization process can remove the optional second sacrificial hard mask and an upper portion of the second gate spacers 56.

After forming the second frontside layer 62, the at least one second sacrificial gate structure is removed utilizing a material removal process that is selective in removing the at least one second sacrificial gate structure. This step reveals the at least one second nanosheet stack. Next, each second sacrificial semiconductor material nanosheet of the at least one second nanosheet stack is removed utilizing a material removal process that is selective in removing the second sacrificial semiconductor material nanosheets. Portions of each second semiconductor channel material nanosheet 54 are now physically exposed.

A second gate structure, which includes second gate dielectric layer 64 and second gate electrode 66 is then formed wrapped around the suspended portions of each second semiconductor channel material nanosheet 54 of the at least one second nanosheet stack; a first gate electrode of a first gate structure will be formed later in the process of the present application. The second gate dielectric layer 60 is composed of a second gate dielectric material that has a dielectric constant of greater than 4.0. Illustrative examples of second gate dielectric materials that can be used in providing the second gate dielectric layer 60 include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The first gate dielectric material can further include dopants such as lanthanum (La), aluminum (Al) and/or magnesium (Mg). The second gate dielectric material can be compositionally the same as, or compositionally different from the first gate dielectric material.

Second gate electrode 66 is composed of a second gate electrode material. The second gate electrode material can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The second gate structure including the second gate dielectric layer 64 and the second gate electrode 66 can be formed by deposition of the second gate dielectric material, and the second gate electrode material, followed by a planarization process.

In some embodiments of the present application, a dielectric anneal step, as defined above, can now be performed after forming the second gate dielectric material to reduce defects that are present in the second gate dielectric layer 64. If no dielectric anneal was performed on the first gate dielectric layer 40, the dielectric anneal used here can reduce the defects in the first gate dielectric layer 40 as well.

Next, second gate cut structures are formed utilizing the same materials and techniques mentioned above in forming the first gate structures. The second gate cut structures include a second inner core dielectric material 70, and a second outer dielectric material liner 68. The second inner core dielectric material 70 includes one of the dielectric materials mentioned above for the first inner core dielectric material 46, and the second outer dielectric material liner 68 includes one of the dielectric materials mentioned above for the first outer dielectric material liner 44.

Referring now to FIGS. 15A, 15B and 15C, there are illustrated the exemplary semiconductor structure shown in FIGS. 14A, 14B and 14C, respectively, after removing the second inner core dielectric material 70 of some of the second gate cut structures, revealing an underlying first deep via structure 48, and forming a second deep via structure 72 contacting the revealed first deep via structure 48. Collectively, the first deep via structure that is in contact with the second deep via structure 72 provides a frontside/backside deep via structure.

The removal the second inner core dielectric material 70 of some of the second gate cut structures includes forming a patterned mask (not shown) on the exemplary structure shown in FIGS. 14A-14C; the patterned mask has openings that physically some of the second gate cut structures. With this patterned mask in place, an etch is employed that selectively removes the second inner core dielectric material 70 relative to the second outer dielectric material liner 68. Another etch is then used to punch through the a horizontal portion of the second outer dielectric material liner 68 and the bonding dielectric layer 50 stopping on a surface of the first deep via structure. Second deep via openings are formed. The patterned mask is now typically removed from the structure. The second deep via structure 72 is then formed into each of the second deep via openings utilizing a metallization process that includes filling (including deposition and planarization) each of the second deep via openings with at least a contact conductor material. The contact conductor material can include, for example, a conductive metal such as W. Cu, Al, Co, Ru, Mo, Os, Ir, Rh, or an alloy thereof. The contact conductor material used in providing the second deep via structure 72 can be composition the same as, or compositionally different from, the contact conductor material used in providing the first deep via structure 72. Typically, and the second deep via structure 72 and the first deep via structure 48 are composed of a compositionally same contact conductor material.

Referring now to FIGS. 16A, 16B and 16C, there are illustrated the exemplary semiconductor structure shown in FIGS. 15A, 15B and 15C, respectively, after forming additional frontside ILD layers having frontside contact structures, metal vias and metal lines embedded therein, a frontside BEOL structure 76, and a carrier wafer 78. The frontside contact structures that are formed include a shared frontside first/second source/drain contact structure 74A, a frontside source/drain contact structure 74B, a frontside shared first/second gate electrode contact structure 74C, and a frontside second gate source/drain contact structure 74D.

In the present application, the additional frontside ILD layers and the first frontside ILD layer 38 provide a frontside dielectric layer 63. The additional frontside ILD layers can be composed of dielectric materials that are compositionally the same as, or compositionally different from, the dielectric material that provides the first frontside ILD layer 38. Typically, the dielectric materials that provide the additional ILD layers are compositionally the same as the dielectric material that provides the first frontside ILD layer 38 such that within the frontside dielectric layer 63, no material interface would exist between the additional frontside ILD layers and the first frontside ILD layer 38; such an embodiment is shown in the drawings of the present application. The additional frontside ILD layers can be formed utilizing one of the deposition processes mentioned above in forming the first frontside ILD layer 38.

Frontside contact structures including the shared frontside first/second source/drain contact structure 74A, the frontside source/drain contact structure 74B, the frontside shared first/second gate electrode contact structure 74C, the frontside second gate source/drain contact structure 74D and the frontside second gate electrode contact structure (not illustrated in the drawings), metal vias V0 and metal lines M1 are formed utilizing metallization processes. In the present application, a lower portion of the frontside dielectric layer 63 is formed, and then the frontside contact structure are formed utilizing a first metallization process. An upper portion if the frontside dielectric layer 63 is then formed and thereafter the V0 and metal lines M1 can be formed utilizing a second metallization process. Each of the first and second metallization processes include forming openings within the frontside dielectric layer 63 thereafter filling (including deposition and planarization) each the opening with at least a contact conductor material. The contact conductor material that can be used for providing the frontside contact structures, V0 and M1 include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures, V0 and M1 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

Next, frontside BEOL structure 76 is formed on the uppermost surface of the frontside dielectric layer 63 such that the metal lines M1 are in contact with the frontside BEOL structure 76. The frontside BEOL structure 76 can include one or more interconnect dielectric material layers (including one of the dielectric materials mentioned above for the first frontside ILD layer 38) that contain frontside metal wires (the metal wires can be composed of any electrically conductive metal or electrically conductive metal alloy) embedded therein.

The carrier wafer 78 can include one of the semiconductor materials mentioned above for the semiconductor substrate 10. Carrier wafer 78 is bonded to the frontside BEOL structure 76 after frontside BEOL structure 76 formation.

Referring now to FIGS. 17A, 17B and 17C, there are illustrated the exemplary semiconductor structure shown in FIGS. 16A, 16B and 16C, respectively, after removing the semiconductor substrate 10. The removal of the semiconductor substrate 10 typically includes flipping the wafer 180° to physically expose a backside of the semiconductor substrate 10. This flipping step is not shown in the drawings of the present application for clarity. This flipping step will allow backside processing of the exemplary structure. Backside processing occurs on a side of a wafer opposite the side which will contain the stacked transistors. Flipping of the structure can be performed by hand or by utilizing a mechanical means such as, for example, a robot arm. The removal of the physically exposed semiconductor substrate 10 physically exposes the etch stop layer 12. The removal of the semiconductor substrate 10 can be performed utilizing a material removal process that is selective in removing the first semiconductor material that provides the semiconductor substrate 10.

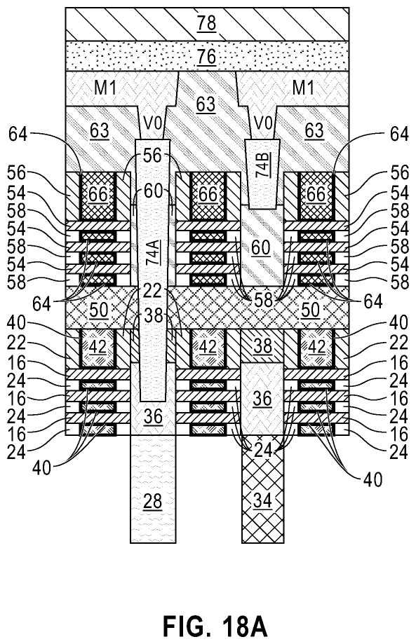

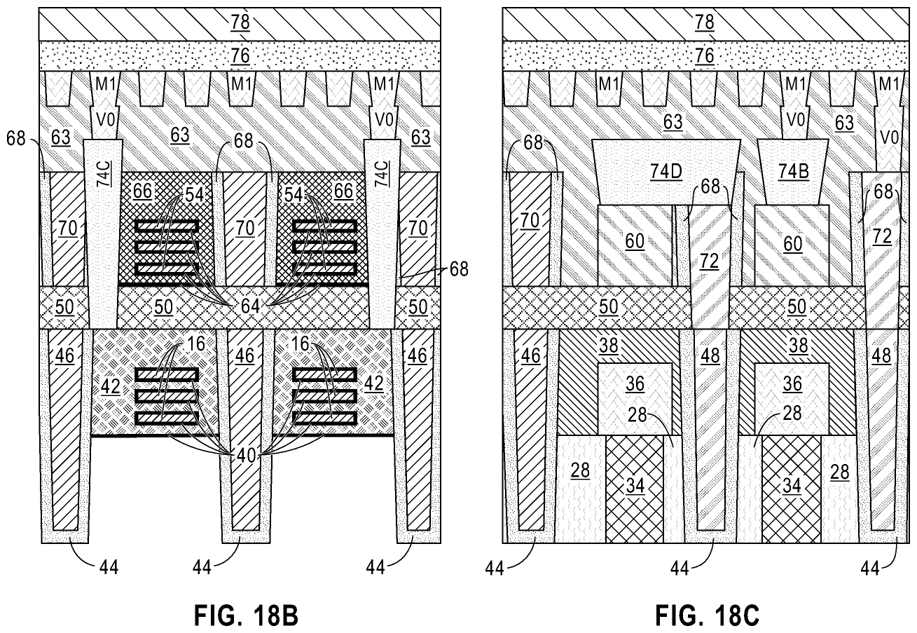

Referring now to FIGS. 18A, 18B and 18C, there are illustrated the exemplary semiconductor structure shown in FIGS. 17A, 17B and 17C, respectively, after removing the etch stop layer 12 to physically expose a portion of the first gate dielectric layer 40. The removal of the etch stop layer 12 includes a material removal process that is selective in removing the etch stop layer 12.

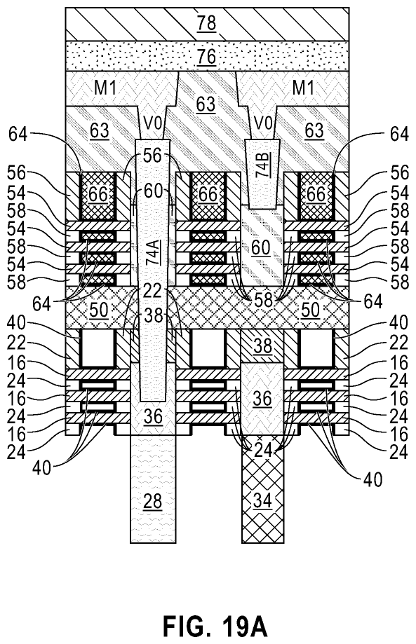

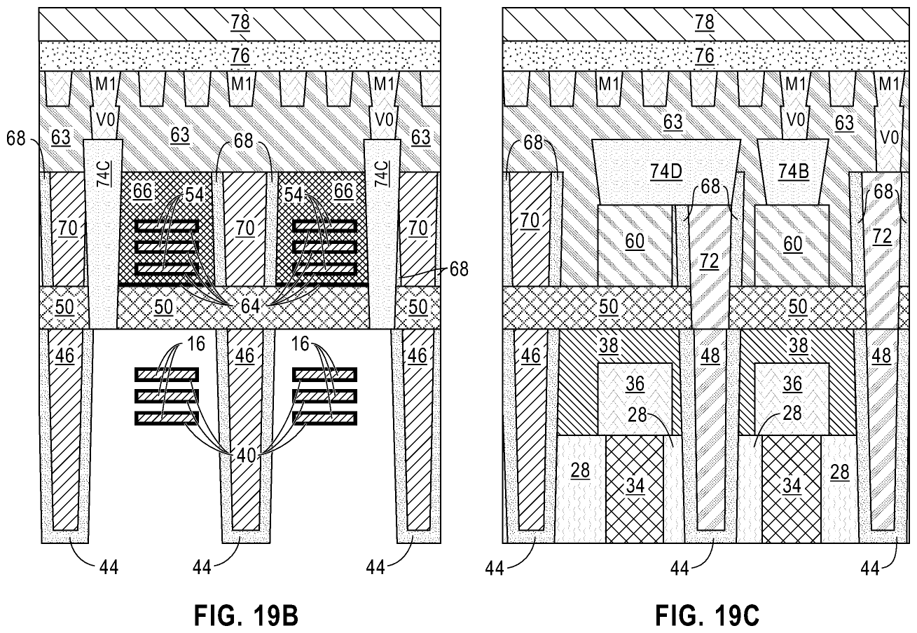

Referring now to FIGS. 19A, 19B and 19C, there are illustrated the exemplary semiconductor structure shown in FIGS. 18A, 18B and 18C, respectively, after removing the physically exposed portion of the first gate dielectric layer 40, and thereafter removing each first gate placeholder structure 42. The physically exposed portion of the first gate dielectric layer 40 can be removed utilizing a material removal process that is selective in removing the first gate dielectric material that provides the first gate dielectric layer 40. This material removal process physically exposes the first gate place holder structures 42. The physically exposed first gate place holder structures 42 can be removed utilizing a material removal process that is selective in removing the first gate place holder structures 42.

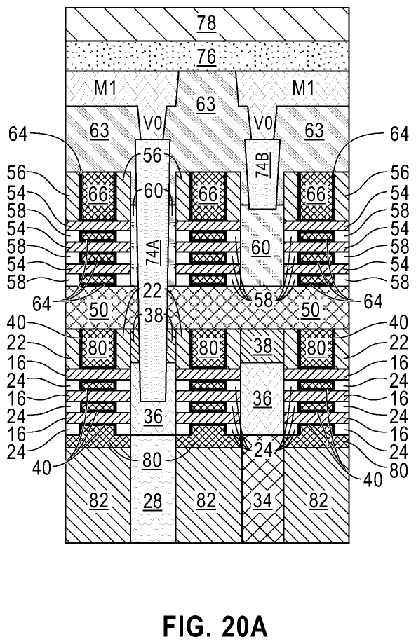

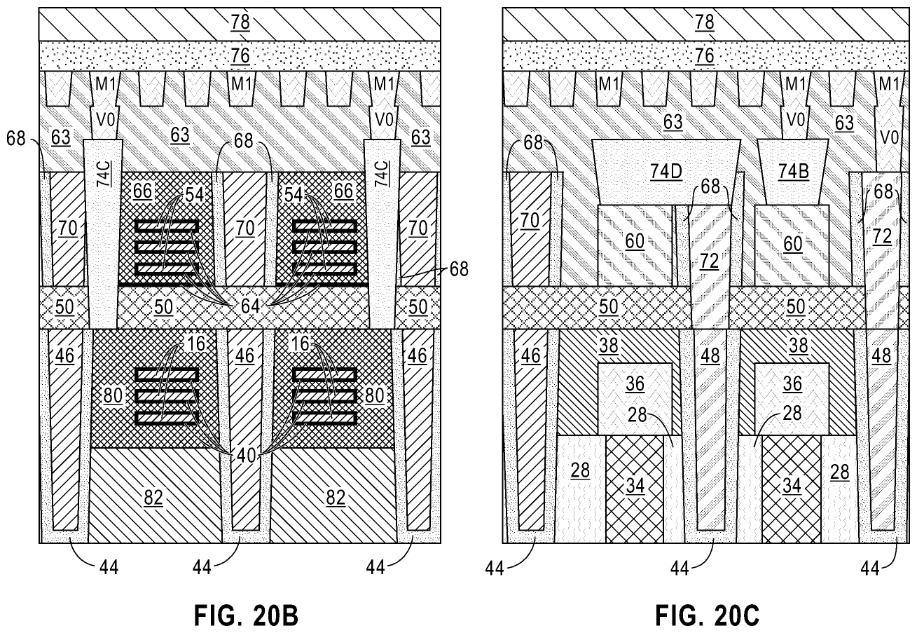

Referring now to FIGS. 20A, 20B and 20C, there are illustrated the exemplary semiconductor structure shown in FIGS. 19A, 19B and 19C, respectively, after forming a first gate electrode 80, recessing the first gate electrode 80 and forming a backside gate dielectric cap 82. The first gate electrode 80 wraps around each first semiconductor channel material nanosheet 16 and is present on the first gate dielectric layer 40. The first gate electrode 80 can be formed by deposition, followed by a recessed etch. Collectively, the first gate electrode 80 and the first gate dielectric layer 40 provide a first gate structure of a first FET.

The first gate electrode 80 is composed of a first gate electrode material. The first gate electrode material can include one of the second gate electrode materials mentioned above. In some embodiments, of the present application, the first gate electrode material can be compositionally the same as the second gate electrode material. In other embodiments, the first gate electrode material is compositionally different from the second gate electrode material. For example, the first gate electrode material that provides the first gate electrode 80 can be composed a n-type WFM, while the second gate electrode material that provides the second gate electrode 66 can be composed of an n-type WFM.

The backside gate dielectric cap 82 is composed of a dielectric material that is compositionally different from the dielectric material that provides the dielectric pillar 28 as well as the dielectric material that provides the first outer dielectric material liner 44. Exemplary dielectric materials that can be used in providing the backside gate dielectric cap 82 include, but are not limited to, silicon dioxide, SiOCH, SiC, silicon nitride or silicon oxynitride. The backside gate dielectric cap 82 can be formed by deposition followed by a planarization process. At this point of the present application, each of the dielectric pillar 28, the backside gate dielectric cap 82, the first outer dielectric material liner 44, and the sacrificial placeholder structure 34 has a bottommost surface that is coplanar with each other as is shown in FIG. 20A.

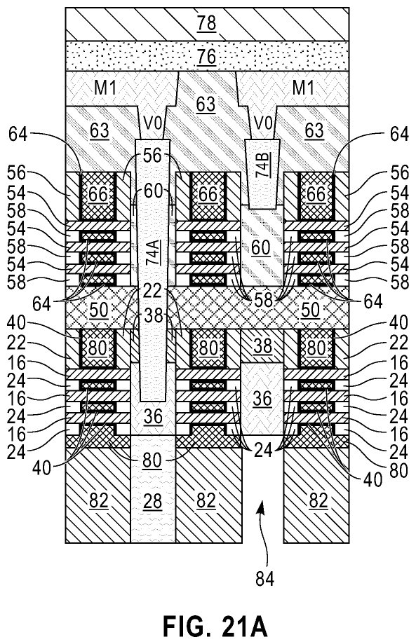

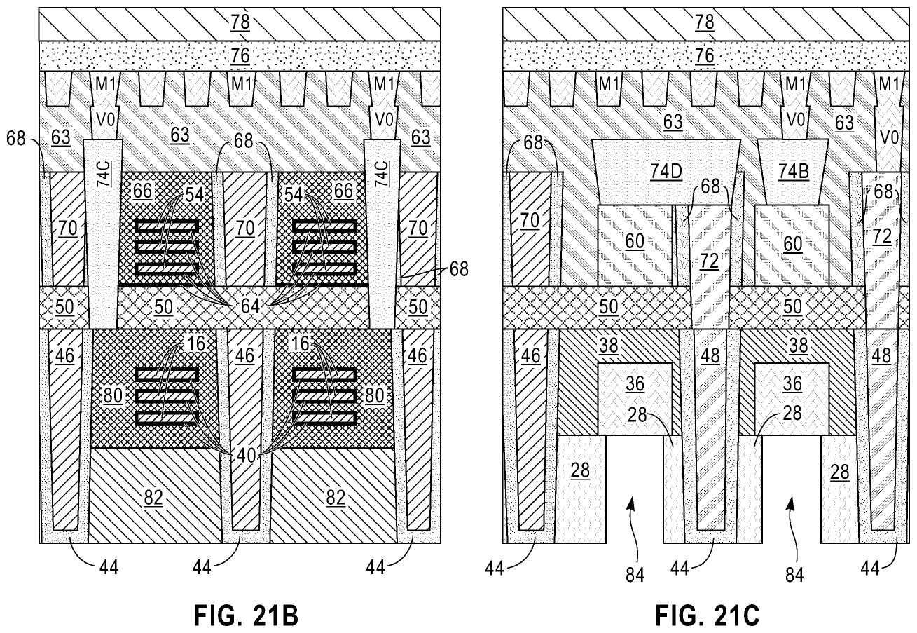

Referring now to FIGS. 21A, 21B and 21C, there are illustrated the exemplary semiconductor structure shown in FIGS. 20A, 20B and 20C, respectively, after removing each sacrificial placeholder structure 34 to provide a backside contact opening 84 that physically exposes some of the first source/drain regions 36. The sacrificial placeholder structure 34 can be removed utilizing a material removal process such as, for example, etching, that is selective in removing the sacrificial placeholder structure 34 from the structure. Other first source/drain regions 36 which contact the dielectric pillar 28 are not physically exposed by this step of the present application.

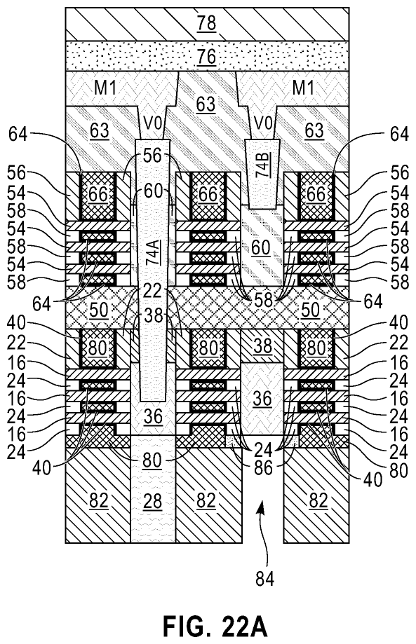

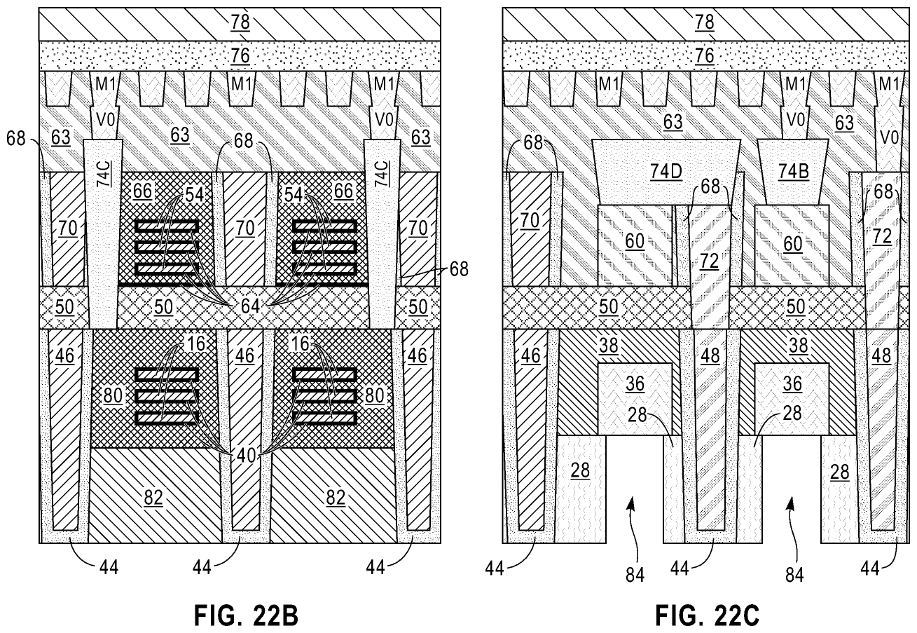

Referring now to FIGS. 22A, 22B and 22C, there are illustrated the exemplary semiconductor structure shown in FIGS. 21A, 21B and 21C, respectively, after laterally recessing a physically exposed sidewall of the first gate electrode 80 and forming an asymmetric inner spacer 86 in the indented region of the first gate electrode 80. The laterally recessing includes an etching process that is selective in removing the first gate electrode material that provides the first gate electrode 80. The asymmetric inner spacer 86 can be composed of one of the spacer dielectric materials mentioned above for the first gate spacers 22. In some embodiments of the present application, the spacer dielectric material that provides the asymmetric inner spacer 86 is compositionally the same as the spacer dielectric material that provides the first inner spacer 24. In other embodiments of the present application, the spacer dielectric material that provides the asymmetric inner spacer 86 is compositionally different from the spacer dielectric material that provides the first inner spacer 24. The asymmetric inner spacer 86 has surface that directly contacts a bottommost first inner spacer 24, and the asymmetric inner spacer 86 has at least an outermost sidewall that is vertically aligned to the outermost sidewall of each first inner spacer 24. As shown in FIG. 22A, the first gate electrode 80 of the middle first FET has a sidewall that directly contacts a sidewall of the dielectric pillar 28, and another sidewall that directly contacts a sidewall of the asymmetric inner spacer 86.

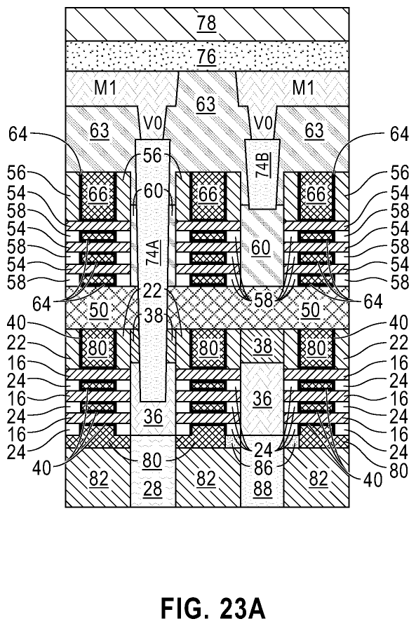

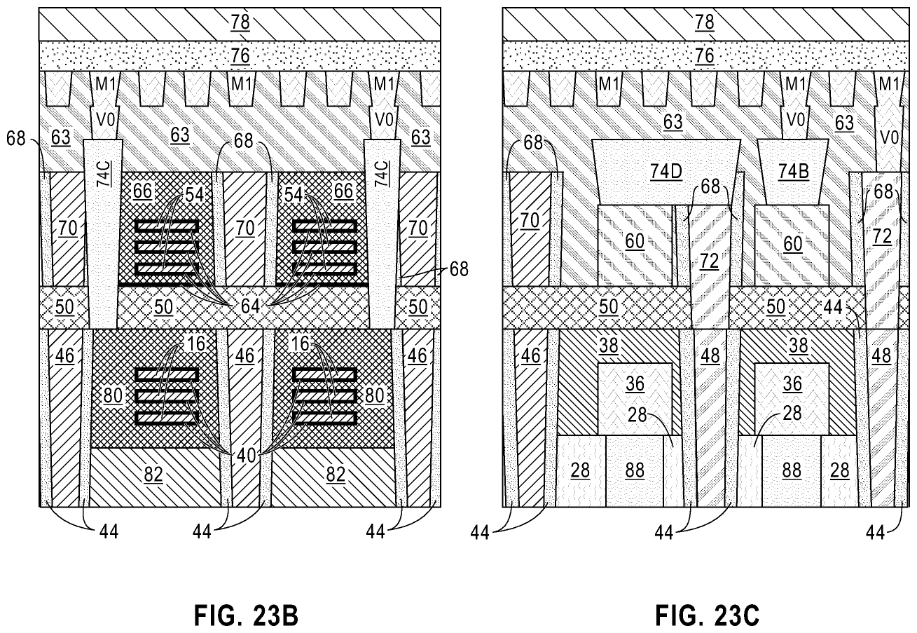

Referring now to FIGS. 23A, 23B and 23C, there are illustrated the exemplary semiconductor structure shown in FIGS. 22A, 22B and 22C, respectively, after forming backside contact structures. The backside contact structures include at least a backside first source/drain gate structure 88; a backside first gate electrode contact structure (not shown) can also be formed. The backside first source/drain gate structure 88 is formed in each backside contact opening 84 mentioned above.

The backside contact structures are formed utilizing a metallization process (deposition and planarization). The backside contact structures including the backside first source/drain gate structure 88 are composed of one of the contact conductor materials mentioned above for providing the frontside contact structures, V0 and M1. The planarization process used in forming the backside contact structures removes a horizontal surface of the first outer dielectric material liner 44. This removal of the first outer dielectric material liner 44 physically exposes the first inner core dielectric material 46 of the first gate cut structure and the first deep via structure 48.

Referring now to FIGS. 24A, 24B and 24C, there are illustrated the exemplary semiconductor structure shown in FIGS. 23A, 23B and 23C, respectively, after forming a backside ILD layer 92 containing backside VDD and VSS power structures embedded therein, and a backside BEOL structure 94. Also, formed is backside metal connector 90. The backside ILD layer 92 is composed of one of the dielectric materials mentioned above for the first frontside ILD layer 38. The backside ILD layer 92 can be formed utilizing one of the deposition processes mentioned above in forming the first frontside ILD layer 38. The backside VDD and VSS power structures are formed utilizing a metallization process (deposition and planarization). The backside VDD and VSS power structures are composed of one of the contact conductor materials mentioned above for providing the frontside contact structures, V0 and M1.

The backside metal connector 90 is composed of one of the contact conductor materials mentioned above for providing the frontside contact structures, V0 and M1. The backside metal connector 90 can be formed by removing a portion of the dielectric pillar 28 that separates one of the backside source/drain contact structure 88 from the frontside/backside deep via structure (combination of the first deep via structure 48 and the second deep via structure 72) and thereafter filling the gap created by removing a portion of the dielectric pillar 28 with one of the above mentioned contact conductor materials. The filling can include deposition and planarization. The backside source/drain contact structure 88 is now connected to the frontside/backside deep via structure (combination of the first deep via structure 48 and the second deep via structure 72) by means of the backside metal connector 90.

The backside BEOL structure 94 is formed in contact with the backside ILD layer 92 containing the embedded backside VDD and VSS power structures. The backside BEOL structure 94 can include one or more interconnect dielectric material layers (including one of the dielectric materials mentioned above for the first frontside ILD layer 38) that contain backside metal wires (the metal wires can be composed of any electrically conductive metal or electrically conductive metal alloy) embedded therein.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first field effect transistor (FET) having a first gate structure and a pair of first source/drain regions;
a second FET stacked over the first FET and having a second gate structure and a pair of second source/drain regions;
a dielectric pillar located beneath the first FET and directly contacting one of the first source/drain regions of the pair of first source/drain regions; and
backside gate dielectric cap located adjacent to the dielectric pillar, wherein the backside gate dielectric cap directly contacts a surface of a first gate electrode of the first gate structure.

2. The semiconductor device of claim 1, wherein the dielectric pillar further comprises a sidewall having a first portion that directly contacts a sidewall of the first gate electrode and a second portion that directly contacts a sidewall of the backside gate dielectric cap.

3. The semiconductor device of claim 1, wherein the dielectric pillar has a height that is greater than a height of the backside gate dielectric cap.

4. The semiconductor device of claim 1, further comprising a backside source/drain contact structure contacting the other first source/drain region of the pair of first source/drain regions.

5. The semiconductor device of claim 4, further comprising an asymmetric inner spacer separating the backside source/drain contact structure from the first gate electrode.

6. The semiconductor device of claim 4, further comprising a backside back-end-of-the-line (BEOL) structure located beneath the first FET and connected to the backside source/drain contact structure by a backside VSS power source.

7. The semiconductor device of claim 4, further comprising a shared frontside source/drain contact structure contacting the first source/drain region of the pair of first source/drain regions that is located on the dielectric pillar and one of the second source/drain regions of the pair of second source/drain regions.

8. The semiconductor device of claim 7, wherein the shared frontside source/drain contact structure is connected to a frontside back-end-of-the-line (BEOL) structure by a metal via and a metal line.

9. The semiconductor device of claim 8, further comprising a frontside source/drain contact structure contacting the other second source/drain region of the pair of second source/drain regions and connected to the frontside BEOL structure by a metal via and at least one metal line.

10. The semiconductor device of claim 8, further comprising a frontside shared first/second gate electrode contact structure contacting both the first gate electrode of the first gate structure, and a second gate electrode of the second gate electrode and connected to the frontside BEOL structure by yet another metal via and a yet another metal line.

11. The semiconductor device of claim 1, wherein the second gate structure comprises a second gate electrode, and wherein the second gate electrode is composed of a compositionally different work function metal than the first gate electrode.

12. The semiconductor device of claim 1, wherein the first gate structure is wrapped around a portion of at least one first semiconductor channel material nanosheet of a first nanosheet stack, and the second gate structure is wrapped around a portion of at least one second semiconductor channel material nanosheet of a second nanosheet stack.

13. The semiconductor device of claim 1, wherein the first FET is spaced apart from the second FET by a bonding dielectric layer.

14. The semiconductor device of claim 1, further comprising a first gate cut structure located adjacent to the first FET, and a second gate cut structure located adjacent to the second FET.

15. The semiconductor device of claim 14, wherein the first gate cut structure comprises a first outer dielectric material liner encasing a first inner core dielectric material, and wherein the second gate cut structure comprises a second outer dielectric material liner encasing a second inner core dielectric material.

16. The semiconductor device of claim 14, wherein the first gate structure and the second gate structure are spaced apart by a bonding dielectric layer.

17. The semiconductor device of claim 1, further comprising a frontside/backside deep via structure having a first end electrically connected to one of the second source/drain regions of the pair of source/drain regions by a frontside second gate source/drain contact structure, and a second end electrically connected to a backside BEOL structure by a VDD power source.

18. The semiconductor device of claim 17, wherein the frontside/backside deep via structure has an upper via portion encased in a second outer dielectric material liner, a lower portion that is encased in a first outer dielectric material liner, and a middle portion that is encased in a bonding dielectric layer that is located between the first FET and the second FET.

19. The semiconductor device of claim 1, wherein the first FET and the second FET are present in a first active area, and wherein at least one other second FET stacked above at least one other first FET are located in a second active area that is spaced apart from the first active area, wherein one source/drain region of the at least one other first FET is electrically connected to a frontside BEOL structure by a combination of a backside source/drain contact structure a backside metal connector, a frontside/backside deep via structure, a metal via and a metal line.

20. The semiconductor device of claim 19, wherein the backside metal connector directly contacts a sidewall of a lower portion of the frontside/backside deep via structure, and a sidewall of the backside source/drain contact structure.

21. A process of forming a stacked field effect transistor (FET) device, the process comprising:
forming at least one precursor first gate structure comprising a first gate dielectric layer located on a surface of at least one first semiconductor channel material, and a first gate placeholder structure on the first gate dielectric layer, wherein the at least one precursor first gate structure includes a pair of first source/drain regions, and wherein a dielectric pillar is located beneath one of the first source/drain regions of the pair of first source/drain regions, and a sacrificial placeholder structure is located beneath the other first source/drain region of the pair of first source/drain regions;
forming at least one second gate structure above the at least one precursor first gate structure, the at least one second gate structure comprising a second gate dielectric layer located on a surface of at least one second semiconductor channel material, a second gate electrode located on the second gate dielectric layer, and a pair of second source/drain regions;
forming at least frontside contact structures and a frontside BEOL structure on top of the second gate structure;
replacing the first gate placeholder structure from a backside the device with a first gate electrode, wherein the replacing converts the at least one precursor first gate structure into at least one first gate structure;
replacing the sacrificial placeholder structure with a backside source/drain contact structure; and
forming at least VSS power supplies and VDD power supplies and a backside BEOL structure.

22. The process of claim 21, further comprising forming at least one first gate cut structure in the first gate placeholder structure, wherein the at least one first gate cut structure comprises a first outer dielectric material liner encasing a first inner core dielectric material.

23. The process of claim 22, further comprising replacing the first inner core dielectric material of at least one of the first gate cut structures with a conductor contact material to form a first deep via structure.

24. The process of claim 23, further comprising forming at least one second gate cut structure in the second gate electrode, wherein the at least one second gate cut structure comprises a second outer dielectric material liner encasing a second inner core dielectric material.

25. The process of claim 24, further comprising replacing the second inner core dielectric material of at least one of the second gate cut structures with a conductor contact material to form a second deep via structure, wherein the second deep via structure directly connects the first deep via structure and together the first and second deep via structures provide a frontside/backside deep via structure.
